(19) United States
(12) Patent Application Publication
(10) Pub. No.: US 2020/0392344 A1
(43) Pub. Date: Dec. 17, 2020

(54) PHOTOSENSITIVE COMPOSITION

(71) Applicant: FUJIFILM Corporation, Tokyo (JP)

(72) Inventors: Yuki NARA, Haibara-gun (JP); Takahiro Okawara, Haibara-gun (JP)

(73) Assignee: FUJIFILM Corporation, Tokyo (JP)

(21) Appl. No.: 17/006,237

(22) Filed: Aug. 28, 2020

Related U.S. Application Data
(63) Continuation of application No. PCT/JP2019/011681, filed on Mar. 20, 2019.

(30) Foreign Application Priority Data
Mar. 26, 2018 (JP) 2018-058035

(51) Int. Cl. C09B 67/20; C08F 2/50; C08F 2/38; C08F 20/14; C08K 5/33; C08K 5/37; C08K 5/22; G03F 7/00; G03F 7/031

(52) U.S. Cl. CPC C09B 67/0064; C08F 2/50; C08F 2/38; C08F 20/14; G03F 7/031; C08K 5/37; C08K 5/22; G03F 7/0007; C08K 5/33

(57) ABSTRACT

Provided is a photosensitive composition including a radically polymerizable compound, a photoradical polymerization initiator, and at least one selected from a chain transfer agent or a radical trapping agent.

### CROSS-REFERENCE TO RELATED APPLICATIONS

This application is a Continuation of PCT International Application No. PCT/JP2019/011681 filed on Mar. 20, 2019, which claims priority under 35 U.S.C. § 119(a) to Japanese Patent Application No. 2018-058035 filed on Mar. 26, 2018. Each of the above application(s) is hereby expressly incorporated by reference, in its entirety, into the present application.

### BACKGROUND OF THE INVENTION

### 1. Field of the Invention

The present invention relates to a photosensitive composition for pulse exposure. More specifically, the present invention relates to a photosensitive composition for pulse exposure used for a solid-state imaging element, a color filter, or the like.

### 2. Description of the Related Art

A color filter or the like is manufactured using a photosensitive composition including a radically polymerizable compound and a photoradical polymerization initiator (refer to JP2012-532334A and KR101573937B).

### SUMMARY OF THE INVENTION

The present inventors conducted an investigation on a photosensitive composition including a radically polymerizable compound and a photoradical polymerization initiator and found that, by exposing the photosensitive composition to pulses of light, curing properties are excellent such that an excellent pattern can be easily formed along an opening shape of a mask. In addition, as a result of further investigation, the present inventors found that, in the case of pulse exposure, an excellent pattern can be easily formed along an opening shape of a mask. For example, even in a case where the exposure dose changes, the line width of the obtained pattern is not likely to be more than or less than an opening size of a mask. Therefore, a pattern having a desired line width can be easily formed by changing an opening size of a mask.

On the other hand, it is also considered to adjust, for example, the formula of a composition such that the line width of the obtained pattern can be adjusted to be more than or less than an opening size of a mask without changing the opening size of the mask.

Accordingly, an object of the present invention is to provide a photosensitive composition for pulse exposure with which the line width of the obtained pattern can be adjusted without changing an opening size of a mask.

According to the investigation, the present inventors found that a photosensitive composition for pulse exposure including a radically polymerizable compound and a photoradical polymerization initiator further includes at least one selected from a chain transfer agent or a radical trapping agent such that the line width of the obtained pattern can be adjusted without changing an opening size of a mask, thereby completing the present invention. Accordingly, the present invention provides the following.
<1> A photosensitive composition for pulse exposure comprising:

a radically polymerizable compound;

a photoradical polymerization initiator; and

at least one selected from a chain transfer agent or a radical trapping agent.
<2> The photosensitive composition according to <1>, further comprising: a coloring material.
<3> The photosensitive composition according to <1> or <2>,

in which the chain transfer agent is at least one selected from a thiol compound, a thiocarbonylthio compound, or an aromatic α-methyl alkenyl dimer.
<4> The photosensitive composition according to <1> or <2>,

in which the radical trapping agent is at least one selected from a hindered phenol compound, a hindered amine compound, an N-oxyl compound, a hydrazyl compound, or a verdazyl compound.
<5> The photosensitive composition according to any one of <1> to <4>,

in which a content of the chain transfer agent is 0.01% to 10 mass % with respect to a total solid content of the photosensitive composition.
<6> The photosensitive composition according to any one of <1> to <5>,

in which a content of the chain transfer agent is 0.1 to 100 parts by mass with respect to 100 parts by mass of the radically polymerizable compound.
<7> The photosensitive composition according to any one of <1> to <6>,

in which a content of the chain transfer agent is 0.2 to 200 parts by mass with respect to 100 parts by mass of the photoradical polymerization initiator.
<8> The photosensitive composition according to any one of <1> to <7>,

in which a content of the radical trapping agent is 0.01% to 10 mass % with respect to a total solid content of the photosensitive composition.
<9> The photosensitive composition according to any one of <1> to <8>,

in which a content of the radical trapping agent is 0.1 to 100 parts by mass with respect to 100 parts by mass of the radically polymerizable compound.
<10> The photosensitive composition according to any one of <1> to <9>,

in which a content of the radical trapping agent is 0.2 to 200 parts by mass with respect to 100 parts by mass of the photoradical polymerization initiator.
<11> The photosensitive composition according to any one of <1> to <10>, further comprising:

a resin having an acid group.
<12> The photosensitive composition according to any one of <1> to <11>, which is a photosensitive composition for pulse exposure to light having a wavelength of 300 nm or shorter.
<13> The photosensitive composition according to any one of <1> to <12>, which is a photosensitive composition for pulse exposure under a condition of a maximum instantaneous illuminance of 50000000 W/m² or higher.
<14> The photosensitive composition according to any one of <1> to <13>, which is a photosensitive composition for a solid-state imaging element.
<15> The photosensitive composition according to any one of <1> to <13>, which is a photosensitive composition for a color filter.

According to the present invention, it is possible to provide a photosensitive composition for pulse exposure with which the line width of the obtained pattern can be adjusted without changing an opening size of a mask.

### DESCRIPTION OF THE PREFERRED EMBODIMENTS

Hereinafter, the details of the present invention will be described.

In this specification, numerical ranges represented by “to” include numerical values before and after “to” as lower limit values and upper limit values.

In this specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In this specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In this specification, a weight-average molecular weight and a number-average molecular weight denote values in terms of polystyrene measured by gel permeation chromatography (GPC).

In this specification, infrared light denotes light in a wavelength range of 700 to 2500 nm.

In this specification, a total solid content denotes the total mass of all the components of the composition excluding a solvent.

In this specification, the term “step” denotes not only an individual step but also a step which is not clearly distinguishable from another step as long as an effect expected from the step can be achieved.

<Photosensitive Composition>

A photosensitive composition according to an embodiment of the present invention is a photosensitive composition for pulse exposure including a radically polymerizable compound, a photoradical polymerization initiator, and at least one selected from a chain transfer agent or a radical trapping agent.

The photosensitive composition according to the embodiment of the present invention is a photosensitive composition for pulse exposure. By exposing the photosensitive composition according to the embodiment of the present invention to pulses of light, a large amount of a radical is instantaneously generated from the component such as the photoradical polymerization initiator in the exposed portion. A large amount of a radical is instantaneously generated in the exposed portion such that a radically polymerizable monomer can be efficiently cured due to an effect of, for example, suppressing deactivation caused by oxygen. Therefore, the photosensitive composition according to the embodiment of the present invention has excellent curing properties and pattern formability. The pulse exposure refers to an exposure method in which light irradiation and rest are repeated in a cycle of a short period of time (for example, a level of milliseconds). With the photosensitive composition according to the embodiment of the present invention, the line width of the obtained pattern can be adjusted without changing an opening size of a mask. That is, in a case where the photosensitive composition according to the embodiment of the present invention includes the radical trapping agent, the line width of the obtained pattern can be reduced. By increasing the mixing amount of the radical trapping agent, the line width of the obtained pattern can be further reduced. In addition, in a case where the photosensitive composition according to the embodiment of the present invention includes the chain transfer agent, the line width of the obtained pattern can be increased. By increasing the mixing amount of the chain transfer agent, the line width of the obtained pattern can be further increased.

In a case where a photosensitive composition including a radically polymerizable compound and a photoradical polymerization initiator is exposed to continuous light such as an i-ray to form a pattern, in the related art, the mixing amount of the photoradical polymerization initiator is adjusted to adjust the line width of the pattern. During pulse exposure of the photosensitive composition, even in a case where the mixing amount of the photoradical polymerization initiator is reduced or increased as described in Examples described below, there is little influence on the line width of the obtained pattern. However, by mixing the chain transfer agent or the radical trapping agent incorporated, the line width can be adjusted, which is a surprising effect.

The photosensitive composition according to the embodiment of the present invention is a photosensitive composition for pulse exposure. Light used for the exposure may be light having a wavelength of longer than 300 nm or light having a wavelength of 300 nm or shorter. From the viewpoint of easily obtaining excellent curing properties, the light used for the exposure is preferably light having a wavelength of 300 nm or shorter, more preferably light having a wavelength of 270 nm or shorter, and still more preferably light having a wavelength of 250 nm or shorter. In addition, the above-described light is preferably light having a wavelength of 180 nm or longer. Specific examples of the light include a KrF ray (wavelength: 248 nm) and an ArF ray (wavelength: 193 nm). From the viewpoint of easily obtaining higher curing properties, a KrF ray (wavelength: 248 nm) is preferable.

It is preferable that the exposure condition of the pulse exposure is the following condition. From the viewpoint of instantaneously generating a large amount of a radical easily, the pulse duration is preferably 100 nanoseconds (ns) or shorter, more preferably 50 nanoseconds or shorter, and still more preferably 30 nanoseconds or shorter. The lower limit of the pulse duration is not particularly limited and may be 1 femtoseconds (fs) or longer or 10 femtoseconds (fs) or longer. From the viewpoint of curing properties, the frequency is preferably 1 kHz or higher, more preferably 2 kHz or higher, and still more preferably 4 kHz or higher. From the viewpoint of easily suppressing deformation of a substrate or the like caused by exposure heat, the upper limit of the frequency is preferably 50 kHz or lower, more preferably 20 kHz or lower, and still more preferably 10 kHz or lower. From the viewpoint of curing properties, the maximum instantaneous illuminance is preferably 50000000 W/m² or higher, more preferably 100000000 W/m² or higher, and still more preferably 200000000 W/m² or higher. In addition, from the viewpoint of high illuminance reciprocity failure, the upper limit of the maximum instantaneous illuminance is preferably 1000000000 W/m² or lower, more preferably 800000000 W/m² or lower, and still more preferably 500000000 W/m² or lower. The pulse duration refers to the length of time during which light is irradiated during a pulse period. In addition, the frequency refers to the number of pulse periods per second. In addition, the maximum instantaneous illuminance refers to an average illuminance within a time during which light is irradiated in a pulse period. In addition, the pulse period refers to a period in which light irradiation and rest during pulse exposure are set as one cycle.

The photosensitive composition according to the embodiment of the present invention is preferably used as a composition for forming a color filter, a light blocking film, an infrared transmitting filter, a filter, or the like. Examples of the color filter include a filter including a colored pixel that allows transmission of light having a specific wavelength. It is preferable that the color filter is a filter including at least one colored pixel selected from a red pixel, a blue pixel, a green pixel, a yellow pixel, a cyan pixel, or a magenta pixel. The infrared transmitting filter is a filter that allows transmission of at least a part of infrared light. Examples of the infrared transmitting filter include a filter satisfying spectral characteristics in which a maximum value of a transmittance in a wavelength range of 400 to 640 nm is 20% or lower (preferably 15% or lower and more preferably 10% or lower) and a minimum value of a transmittance in a wavelength range of 1100 to 1300 nm is 70% or higher (preferably 75% or higher and more preferably 80% or higher). It is preferable that the infrared transmitting filter is a filter satisfying any one of the following spectral characteristics (1) to (4).

(1): a filter in which a maximum value of a transmittance in a wavelength range of 400 to 640 nm is 20% or lower (preferably 15% or lower and more preferably 10% or lower) and a minimum value of a transmittance in a wavelength range of 800 to 1300 nm is 70% or higher (preferably 75% or higher and more preferably 80% or higher)

(2): a filter in which a maximum value of a transmittance in a wavelength range of 400 to 750 nm is 20% or lower (preferably 15% or lower and more preferably 10% or lower) and a minimum value of a transmittance in a wavelength range of 900 to 1300 nm is 70% or higher (preferably 75% or higher and more preferably 80% or higher)

(3): a filter in which a maximum value of a transmittance in a wavelength range of 400 to 830 nm is 20% or lower (preferably 15% or lower and more preferably 10% or lower) and a minimum value of a transmittance in a wavelength range of 1000 to 1300 nm is 70% or higher (preferably 75% or higher and more preferably 80% or higher)

(4): a filter in which a maximum value of a transmittance in a wavelength range of 400 to 950 nm is 20% or lower (preferably 15% or lower and more preferably 10% or lower) and a minimum value of a transmittance in a wavelength range of 1100 to 1300 nm is 70% or higher (preferably 75% or higher and more preferably 80% or higher)

In a case where the photosensitive composition according to the embodiment of the present invention is used as a composition for an infrared transmitting filter, it is preferable that the photosensitive composition according to the embodiment of the present invention satisfies spectral characteristics in which a ratio A min/B max of a minimum value A min of an absorbance of the photosensitive composition in a wavelength range of 400 to 640 nm to a maximum value B max of an absorbance of the photosensitive composition in a wavelength range of 1100 to 1300 nm is 5 or higher. A min/B max is more preferably 7.5 or higher, still more preferably 15 or higher, and still more preferably 30 or higher.

An absorbance Aλ at a wavelength λ is defined by the following Expression (1).

Aλ=−log(Tλ/100) (1)

Aλ represents the absorbance at the wavelength λ, and Tλ represents a transmittance (%) at the wavelength λ.

In the present invention, a value of the absorbance may be a value measured in the form of a solution or a value of a film which is formed using the photosensitive composition. In a case where the absorbance is measured in the form of the film, it is preferable that the absorbance is measured using a film that is formed by applying the photosensitive composition to a glass substrate using a method such as spin coating such that the thickness of the dried film is a predetermined value, and drying the applied composition using a hot plate at 100° C. for 120 seconds.

In a case where the photosensitive composition according to the embodiment of the present invention is used as a composition for an infrared transmitting filter, it is more preferable that the photosensitive composition according to the embodiment of the present invention satisfies any one of the following spectral characteristics (11) to (14).

(11): A ratio A min1/B max1 of a minimum value A min1 of an absorbance of the photosensitive composition in a wavelength range of 400 to 640 nm to a maximum value B max1 of an absorbance of the photosensitive composition in a wavelength range of 800 to 1300 nm is 5 or higher, preferably 7.5 or higher, more preferably 15 or higher, and still more preferably 30 or higher. In this aspect, a film that can block light in a wavelength range of 400 to 640 nm and allows transmission of light having a wavelength of 720 nm or longer can be formed.

(12): A ratio A min2/B max2 of a minimum value A min2 of an absorbance of the photosensitive composition in a wavelength range of 400 to 750 nm to a maximum value B max2 of an absorbance of the photosensitive composition in a wavelength range of 900 to 1300 nm is 5 or higher, preferably 7.5 or higher, more preferably 15 or higher, and still more preferably 30 or higher. In this aspect, a film that can block light in a wavelength range of 400 to 750 nm and allows transmission of light having a wavelength of 850 nm or longer can be formed.

(13): A ratio A min3/B max3 of a minimum value A min3 of an absorbance of the photosensitive composition in a wavelength range of 400 to 850 nm to a maximum value B max3 of an absorbance of the photosensitive composition in a wavelength range of 1000 to 1300 nm is 5 or higher, preferably 7.5 or higher, more preferably 15 or higher, and still more preferably 30 or higher. In this aspect, a film that can block light in a wavelength range of 400 to 850 nm and allows transmission of light having a wavelength of 940 nm or longer can be formed.

(14): A ratio A min4/B max4 of a minimum value A min4 of an absorbance of the photosensitive composition in a wavelength range of 400 to 950 nm to a maximum value B max4 of an absorbance of the photosensitive composition in a wavelength range of 1100 to 1300 nm is 5 or higher, preferably 7.5 or higher, more preferably 15 or higher, and still more preferably 30 or higher. In this aspect, a film that can block light in a wavelength range of 400 to 950 nm and allows transmission of light having a wavelength of 1040 nm or longer can be formed.

The photosensitive composition according to the embodiment of the present invention can be preferably used as a photosensitive composition for a solid-state imaging element. In addition, the photosensitive composition according to the embodiment of the present invention can be preferably used as a photosensitive composition for a color filter. Specifically, the photosensitive composition according to the embodiment of the present invention can be preferably used as a photosensitive composition for forming a pixel of a color filter, and can be more preferably used as a photosensitive composition for forming a pixel of a color filter used in a solid-state imaging element.

Hereinafter, each of the components used in the photosensitive composition according to the embodiment of the present invention will be described.

<<Radically Polymerizable Compound>>

The photosensitive composition according to the embodiment of the present invention includes the radically polymerizable compound. Examples of the radically polymerizable compound include a compound having an ethylenically unsaturated bond group such as a vinyl group, an allyl group, a methallyl group, a styrene group, a styryl group, or a (meth)acryloyl group.

The radically polymerizable compound may be a monomer (hereinafter, also referred to as “radically polymerizable monomer”) or a polymer (hereinafter, also referred to as “radically polymerizable polymer”). The molecular weight of the radically polymerizable monomer is preferably lower than 2000, more preferably 1500 or lower, and still more preferably 1000 or lower. The lower limit is preferably 100 or higher and more preferably 150 or higher. The weight-average molecular weight (Mw) of the radically polymerizable polymer is preferably 2000 to 2000000. The upper limit is preferably 1000000 or lower and more preferably 500000 or lower. The lower limit is preferably 3000 or higher and more preferably 5000 or higher. The radically polymerizable polymer can also be used as a resin described below.

In the present invention, a combination of a radically polymerizable monomer and a radically polymerizable polymer may be used as the radically polymerizable compound. By using a combination of a radically polymerizable monomer and a radically polymerizable polymer, application properties and curing properties can be easily improved. In a case where a combination of a radically polymerizable monomer and a radically polymerizable polymer is used, the content of the polymerizable monomer is preferably 10 to 1000 parts by mass, more preferably 20 to 500 parts by mass, and still more preferably 50 to 200 parts by mass with respect to 100 parts by mass of the polymerizable polymer.

(Radically Polymerizable Monomer)

The radically polymerizable monomer is preferably a compound (a compound having two or more functional groups) having two or more radically polymerizable groups (preferably two or more ethylenically unsaturated bond groups), more preferably a compound having 2 to 15 radically polymerizable groups (compound having 2 to 15 functional groups), still more preferably a compound having 2 to 10 radically polymerizable groups (compound having 2 to 10 functional groups), and still more preferably a compound having 2 to 6 radically polymerizable groups (compound having 2 to 6 functional groups). Specifically, the radically polymerizable monomer is preferably a (meth)acrylate compound having two or more functional groups, more preferably a (meth)acrylate compound having 2 to 15 functional groups, still more preferably a (meth)acrylate compound having 2 to 10 functional groups, and still more preferably a (meth)acrylate compound having 2 to 6 functional groups. Specific examples of the polymerizable monomer include compounds described in paragraphs “0095” to “0108” of JP2009-288705A, paragraph “0227” of JP2013-029760A and paragraphs “0254” to “0257” of JP2008-292970A, the contents of which are incorporated herein by reference.

The radically polymerizable group value of the radically polymerizable monomer is preferably 1 mmol/g or higher, more preferably 6 mmol/g or higher, and still more preferably 10 mmol/g or higher. The upper limit is preferably 30 mmol/g or lower. The radically polymerizable group value of the radically polymerizable monomer can be calculated by dividing the number of radically polymerizable groups in one molecule of the polymerizable monomer by the molecular weight of the radically polymerizable monomer. In addition, the ethylenically unsaturated bond group value (hereinafter, also referred to as “C═C value”) of the radically polymerizable monomer is preferably 1 mmol/g or higher, more preferably 6 mmol/g or higher, and still more preferably 10 mol/g or higher from the viewpoint of improving curing properties. The upper limit is preferably 30 mmol/g or lower. The C═C value of the radically polymerizable monomer can be calculated by dividing the number of ethylenically unsaturated bond groups in one molecule of the polymerizable monomer by the molecular weight of the radically polymerizable monomer.

It is also preferable that a radically polymerizable monomer having a fluorene skeleton is used as the radically polymerizable monomer. It is presumed that, even in a case where a large amount of a radical is instantaneously generated from the photoradical polymerization initiator due to pulse exposure, for example, a self-reaction in which radically polymerizable groups react with each other in the same molecule is not likely to occur in the radically polymerizable monomer having a fluorene skeleton. As a result, the radically polymerizable monomer can be efficiently cured by pulse exposure, and a film having a high crosslinking density or the like can be formed.

It is preferable that the radically polymerizable monomer having a fluorene skeleton is a compound having a partial structure represented by Formula (Fr). In addition, the radically polymerizable monomer having a fluorene skeleton is preferably a compound having two or more ethylenically unsaturated bond groups, more preferably a compound having 2 to 15 ethylenically unsaturated bond groups, still more preferably a compound having 2 to 10 ethylenically unsaturated bond groups, and still more preferably a compound having 2 to 6 ethylenically unsaturated bond groups.

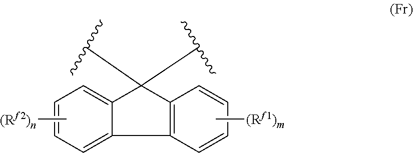

In the formula, a wave line represents a direct bond, R^{f1} and R^{f2} each independently represent a substituent, and m and n each independently represent an integer of 0 to 5. In a case where m represents 2 or more, m R^{f1}'s may be the same as or different from each other, or two R^{f1}'s among m R^{f1}'s may be bonded to each other to form a ring. In a case where n represents 2 or more, n R^{f2}'s may be the same as or different from each other, or two R^{f2}'s among n R^{f2}'s may be bonded to each other to form a ring. Examples of the substituent represented by R^{f1} and R^{f2} include a halogen atom, a cyano group, a nitro group, an alkyl group, an aryl group, a heteroaryl group, —OR^{f11}, —COR^{f12}, —COOR^{f13}, —OCOR^{f14}, —NR^{f15}R^{f16}, —NHCOR^{f17}, —CONR^{f18}R^{f19}, —NHCONR^{f20}R^{f21}, —NHCOOR^{f22}, —SR^{f23}, —SO₂R^{f24}, —SO₂OR^{f25}, —NHSO₂R^{f26}, and —SO₂NR^{f27}R^{f28}. R^{f11} to R^{f28} each independently represents a hydrogen atom, an alkyl group, an aryl group, or a heteroaryl group.

Specific examples of the radically polymerizable monomer having a fluorene skeleton include a compound having the following structure. In addition, examples of a commercially available product of the radically polymerizable monomer having a fluorene skeleton include OGSOL EA-0200 and EA-0300 (manufactured by Osaka Gas Chemicals Co., Ltd., a (meth)acrylate monomer having a fluorene skeleton).

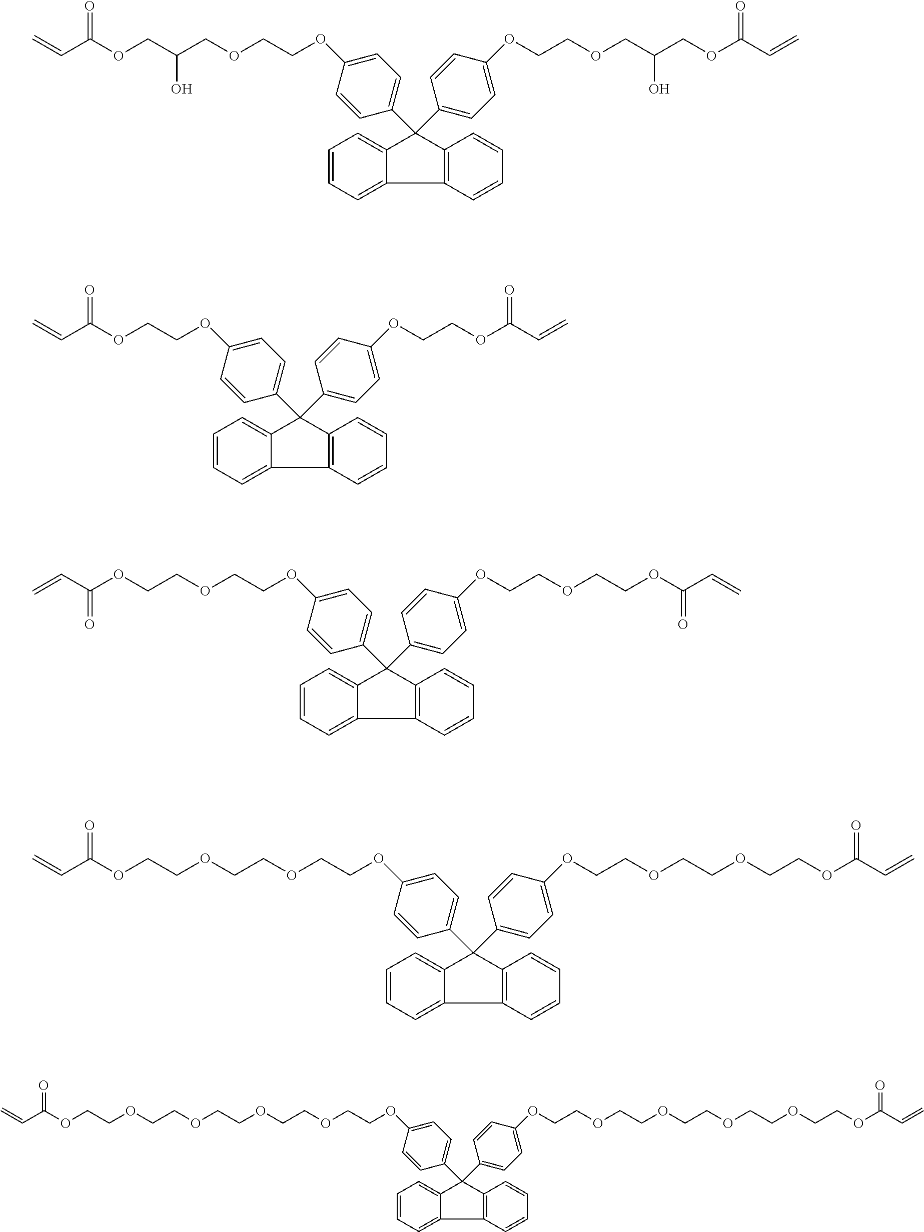

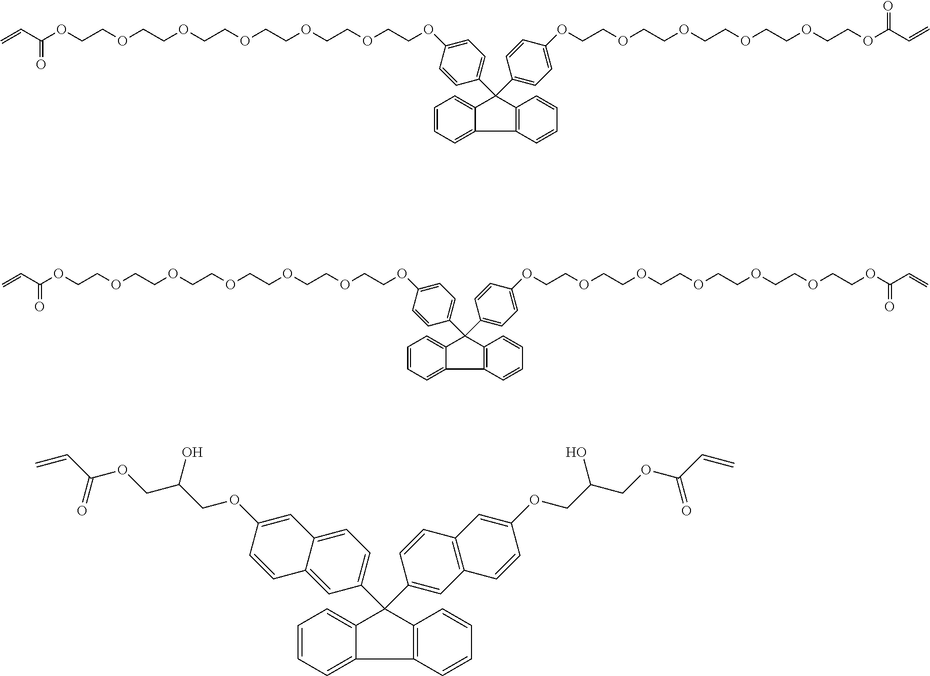

As the radically polymerizable monomer, compounds represented by the following Formulae (MO-1) to (MO-6) can also be preferably used. In a case where T in the formulae represents an oxyalkylene group, a terminal thereof on a carbon atom side is bonded to R.

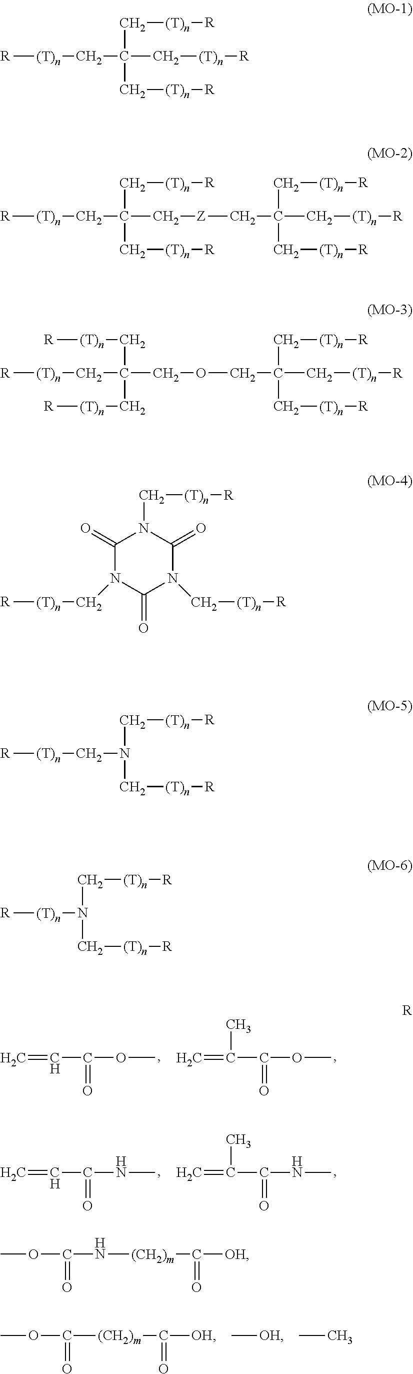

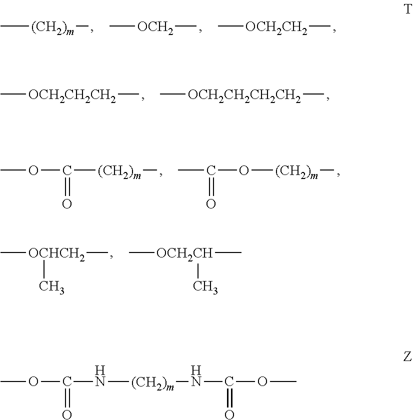

In the formulae, n represents 0 to 14, and m represents 1 to 8. A plurality of R's and a plurality of T's which are present in one molecule may be the same as or different from each other.

At least one of a plurality of R's which are present in each of the compounds represented by Formula (MO-1) to (MO-6) represents —OC(═O)CH═CH₂, —OC(═O)C(CH₃)═CH₂, —NHC(═O)CH═CH₂, or —NHC(═O)C(CH₃)═CH₂.

Specific examples of the compounds represented by Formulae (MO-1) to (MO-6) include compounds described in paragraphs “0248” to “0251” of JP2007-269779A.

It is also preferable that the radically polymerizable monomer is a compound having a caprolactone structure. As the compound having a caprolactone structure, a compound represented by the following Formula (Z-1) is preferable.

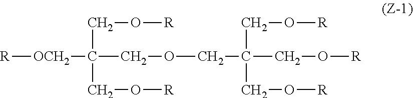

In Formula (Z-1), all of six R's represent a group represented by Formula (Z-2), or one to five R's among the six R's represent a group represented by Formula (Z-2) and the remaining R's represent a group represented by Formula (Z-3), an acid group, or a hydroxy group.

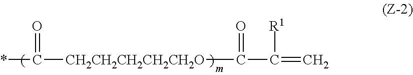

In Formula (Z-2), R¹ represents a hydrogen atom or a methyl group, m represents an integer of 1 or 2, and “*” represents a direct bond.

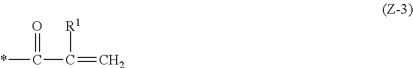

In Formula (Z-3), R¹ represents a hydrogen atom or a methyl group, and “*” represents a direct bond.

As the radically polymerizable monomer, a compound represented by Formula (Z-4) or (Z-5) can also be used.

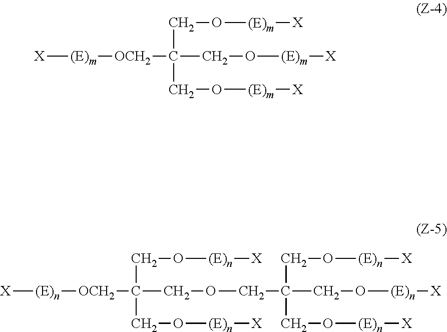

In Formulae (Z-4) and (Z-5), E's each independently represent —((CH₂)_{y}CH₂O)— or —((CH₂)_{y}CH(CH₃)O)—, y's each independently represent an integer of 0 to 10, and X's each independently represent a (meth)acryloyl group, a hydrogen atom, or a carboxyl group. In Formula (Z-4), the total number of (meth)acryloyl groups is 3 or 4, m's each independently represent an integer of 0 to 10, and the sum of m's is an integer of 0 to 40. In Formula (Z-5), the total number of (meth)acryloyl groups is 5 or 6, n's each independently represent an integer of 0 to 10, and the sum of n's is an integer of 0 to 60.

In Formula (Z-4), m represents preferably an integer of 0 to 6 and more preferably an integer of 0 to 4. In addition, the sum of m's is preferably an integer of 2 to 40, more preferably an integer of 2 to 16, and still more preferably an integer of 4 to 8.

In Formula (Z-5), n represents preferably an integer of 0 to 6 and more preferably an integer of 0 to 4. In addition, the sum of n's is preferably an integer of 3 to 60, more preferably an integer of 3 to 24, and still more preferably an integer of 6 to 12.

In addition, it is preferable that, in —((CH₂)_{y}CH₂O)— or —((CH₂)_{y}CH(CH₃)O)— of Formula (Z-4) or (Z-5), a terminal thereof on an oxygen atom side is bonded to X.

In addition, as the radically polymerizable monomer, for example, a compound described in JP2017-048367A, JP6057891B, or JP6031807B, a compound described in JP2017-194662A, 8UH-1006 or 8UH-1012 (manufactured by Taisei Fine Chemical Co., Ltd.), or LIGHT ACRYLATE POB-A0 (manufactured by Kyoeisha Chemical Co., Ltd.) is also preferably used.

(Radically Polymerizable Polymer)

Examples of the radically polymerizable polymer include a resin that includes a repeating unit having a radically polymerizable group.

Examples of the repeating unit having a radically polymerizable group include the following (A2-1) to (A2-4).

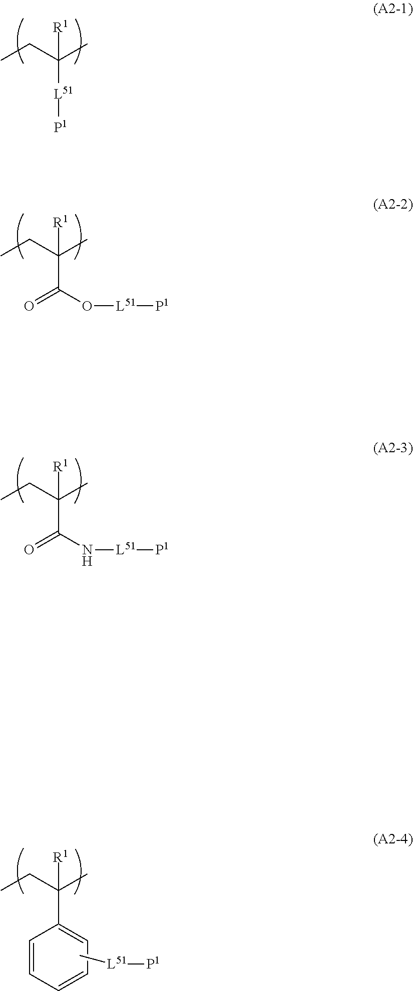

R¹ represents a hydrogen atom or an alkyl group. The number of carbon atoms in the alkyl group is preferably 1 to 5, more preferably 1 to 3, and still more preferably 1. It is preferable that R¹ represents a hydrogen atom or a methyl group.

L⁵¹ represents a single bond or a divalent linking group. Examples of the divalent linking group include an alkylene group, an arylene group, —O—, —S—, —CO—, —COO—, —OCO—, —SO₂—, —NR¹⁰— (R¹⁰ represents a hydrogen atom or an alkyl group and preferably a hydrogen atom), and a group consisting of a combination thereof. The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10.

P¹ represents a radically polymerizable group. Examples of the radically polymerizable group include an ethylenically unsaturated bond group such as a vinyl group, an allyl group, a methallyl group, a styrene group, a styryl group, or a (meth)acryloyl group.

The radically polymerizable group value of the radically polymerizable polymer is preferably 0.5 to 3 mmol/g. The upper limit is preferably 2.5 mmol/g or lower and more preferably 2 mmol/g or lower. The lower limit is preferably 0.9 mmol/g or higher and more preferably 1.2 mmol/g or higher. The radically polymerizable group value of the radically polymerizable polymer refers to a numerical value representing the molar amount of the radically polymerizable group value per 1 g of the solid content of the radically polymerizable polymer. In addition, the C═C value of the radically polymerizable polymer is preferably 0.6 to 2.8 mmol/g. The upper limit is preferably 2.3 mmol/g or lower and more preferably 1.8 mmol/g or lower. The lower limit is preferably 1.0 mmol/g or higher and more preferably 1.3 mmol/g or higher. The C═C value of the radically polymerizable polymer refers to a numerical value representing the molar amount of the ethylenically unsaturated bond group per 1 g of the solid content of the radically polymerizable polymer.

It is also preferable that the radically polymerizable polymer includes a repeating unit having an acid group. The above-described polymer can be used as an alkali-soluble resin. Examples of the acid group include a carboxyl group, a phosphate group, a sulfo group, and a phenolic hydroxy group. Among these, a carboxyl group is preferable. In a case where the radically polymerizable polymer includes a repeating unit having an acid group, the acid value of the radically polymerizable polymer is preferably 30 to 200 mgKOH/g. The lower limit is preferably 50 mgKOH/g or higher, more preferably 70 mgKOH/g or higher, and still more preferably 100 mgKOH/g or higher. The upper limit is preferably 180 mgKOH/g or lower and more preferably 150 mgKOH/g or lower.

Specific examples of the radically polymerizable polymer include a resin having the following structure. In the following structural formulae, Me represents a methyl group.

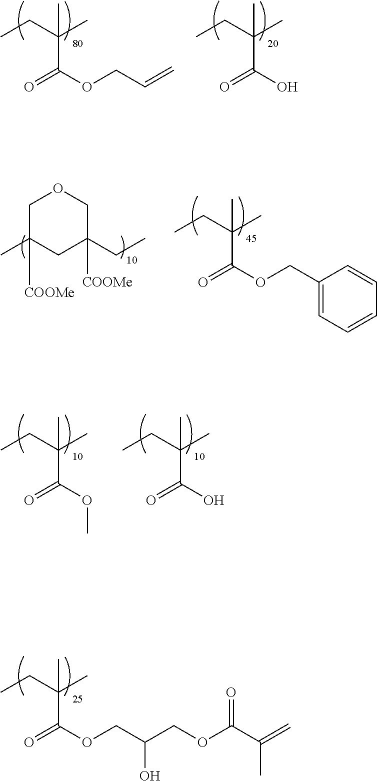

The content of the radically polymerizable compound is preferably 30 mass % or lower, more preferably 20 mass % or lower, and still more preferably 15 mass % or lower with respect to the total solid content of the photosensitive composition. From the viewpoint of curing properties, the lower limit is preferably 3 mass % or higher, more preferably 5 mass % or higher, and still more preferably 8 mass % or higher.

From the viewpoint of easily suppressing pattern thickening, the content of the radically polymerizable monomer is preferably 15 mass % or lower, more preferably 10 mass % or lower, and still more preferably 5 mass % or lower with respect to the total solid content of the photosensitive composition. From the viewpoint of curing properties, the lower limit is preferably 1 mass % or higher, more preferably 3 mass % or higher, and still more preferably 5 mass % or higher.

<<Photoradical Polymerization Initiator>>

The photosensitive composition according to the embodiment of the present invention includes the photoradical polymerization initiator. It is preferable that the photoradical polymerization initiator is a compound that reacts with light having a wavelength of 300 nm or shorter to generate a radical.

It is also preferable that the photoradical polymerization initiator is a compound that is likely to cause two-photon absorption to occur. The two-photon absorption refers to an excitation process of simultaneously absorbing two photons.

It is preferable that the photoradical polymerization initiator is at least one compound selected from an alkylphenone compound, an acylphosphine compound, a benzophenone compound, a thioxanthone compound, a triazine compound, or an oxime compound, and it is more preferable that the photoradical polymerization initiator B is an oxime compound.

Examples of the alkylphenone compound include a benzyldimethylketal compound, an α-hydroxyalkylphenone compound, and an α-aminoalkylphenone compound.

Examples of the benzyldimethylketal compound include 2,2-dimethoxy-2-phenylacetophenone. Examples of a commercially available product include IRGACURE-651 (manufactured by BASF SE).

Examples of the α-hydroxyalkylphenone compound include 1-hydroxy-cyclohexyl-phenyl-ketone, 2-hydroxy-2-methyl-1-phenyl-propane-1-one, 1-[4-(2-hydroxyethoxy)-phenyl]-2-hydroxy-2-methyl-1-propane-1-one, and 2-hydroxy-1-{4-[4-(2-hydroxy-2-methyl-propionyl)-benzyl]phenyl}-2-methyl-propane-1-one. Examples of a commercially available product of the α-hydroxyalkylphenone compound include IRGACURE-184, DAROCUR-1173, IRGACURE-500, IRGACURE-2959, and IRGACURE-127 (all of which are manufactured by BASF SE).

Examples of the α-aminoalkylphenone compound include 2-methyl-1-(4-methylthiophenyl)-2-morpholinopropan-1-one, 2-benzyl-2-dimethylamino-1-(4-morpholinophenyl)-1-butanone, and 2-dimethylamino-2-[(4-methylphenyl)methyl]-1-[4-(4-morpholinyl)phenyl]-1-butanone. Examples of a commercially available product of the α-aminoalkylphenone compound include IRGACURE-907, IRGACURE-369, and IRGACURE-379 (all of which are manufactured by BASF SE).

Examples of the acylphosphine compound include 2,4,6-trimethylbenzoyl-diphenyl-phosphine oxide and bis(2,4,6-trimethylbenzoyl)-phenylphosphine oxide. Examples of a commercially available product of the acylphosphine compound include IRGACURE-819 and IRGACURE-TPO (all of which are manufactured by BASF SE).

Examples of the benzophenone compound include benzophenone, methyl o-benzoylbenzoate, 4-phenylbenzophenone, 4-benzoyl-4′-methyldiphenyl sulfide, 3,3′,4,4′-tetra(t-butyl peroxy carbonyl)benzophenone, and 2,4,6′-trimethyl benzophenone.

Examples of the thioxanthone compound include 2-isopropylthioxanthone, 4-isopropylthioxanthone, 2,4-diethylthioxanthone, 2,4-dichlorothioxanthone, and 1-chloro-4-propoxythioxanthone.

Examples of the triazine compound include 2,4-bis(trichloromethyl)-6-(4-methoxyphenyl)-1,3,5-triazine, 2,4-bis(trichloromethyl)-6-(4-methoxynaphthyl)-1,3,5-triazine, 2,4-bis(trichloromethyl)-6-piperonyl-1,3,5-triazine, 2,4-bis(trichloromethyl)-6-(4-methoxyscrew)-1,3,5-triazine, 2,4-bis(trichloromethyl)-6-[2-(5-methylfuran-2-yl)ethenyl]-1,3,5-triazine, 2,4-bis(trichloromethyl)-6-[2-(furan-2-yl)ethenyl]-1,3,5-triazine, 2,4-bis(trichloromethyl)-6-[2-(4-di ethylamino-2-methyl phenyl)ethenyl]-1,3,5-triazine, and 2,4-bis(trichloromethyl)-6-[2-(3,4-dimethoxyphenyl)ethenyl]-1,3,5-triazine.

Examples of the oxime compound include a compound described in JP2001-233842A, a compound described in JP2000-080068A, a compound described in JP2006-342166A, a compound described in J. C. S. Perkin II (1979, pp. 1653 to 1660), a compound described in J. C. S. Perkin II (1979, pp. 156 to 162), a compound described in Journal of Photopolymer Science and Technology (1995, pp. 202 to 232), a compound described in JP2000-066385A, a compound described in JP2000-080068A, a compound described in JP2004-534797A, a compound described in JP2006-342166A, a compound described in JP2017-019766A, a compound described in JP6065596B, a compound described in WO2015/152153A, and a compound described in WO2017/051680A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product of the oxime compound include IRGACURE-OXE01, IRGACURE-OXE02, IRGACURE-OXE03, or IRGACURE-OXE04 (all of which are manufactured by BASF SE), TR-PBG-304 (manufactured by Changzhou Tronly New Electronic Materials Co., Ltd.), and ADEKA OPTOMER N-1919 (manufactured by Adeka Corporation, a photopolymerization initiator 2 described in JP2012-014052A). As the oxime compound, a compound having no colorability or a compound having high transparency that is not likely to discolor other components can also be preferably used. Examples of a commercially available product of the oxime compound include ADEKA ARKLS NCI-730, NCI-831, and NCI-930 (all of which are manufactured by Adeka Corporation).

In addition, an oxime compound having a fluorene ring can also be used as the oxime compound. Specific examples of the oxime compound having a fluorene ring include a compound described in JP2014-137466A. The content of this specification is incorporated herein by reference.

In addition, an oxime compound having a fluorine atom can also be used as the oxime compound. Specific examples of the oxime compound having a fluorine atom include a compound described in JP2010-262028A, Compound 24 and 36 to 40 described in JP2014-500852A, and Compound (C-3) described in JP2013-164471A. The content of this specification is incorporated herein by reference.

In addition, as the oxime compound, an oxime compound having a nitro group can be used. It is preferable that the oxime compound having a nitro group is a dimer. Specific examples of the oxime compound having a nitro group include compounds described in paragraphs “0031” to “0047” of JP2013-114249A and paragraphs “0008” to “0012” and “0070” to “0079” of JP2014-137466A, compounds described in paragraphs “0007” to 0025″ of JP4223071B, and ADEKAARKLS NCI-831 (manufactured by Adeka Corporation).

In the present invention, as the oxime compound, an oxime compound having a benzofuran skeleton can also be used. Specific examples include OE-01 to OE-75 described in WO2015/036910A.

Hereinafter, specific examples of the oxime compound which are preferably used in the present invention are shown below, but the present invention is not limited thereto.

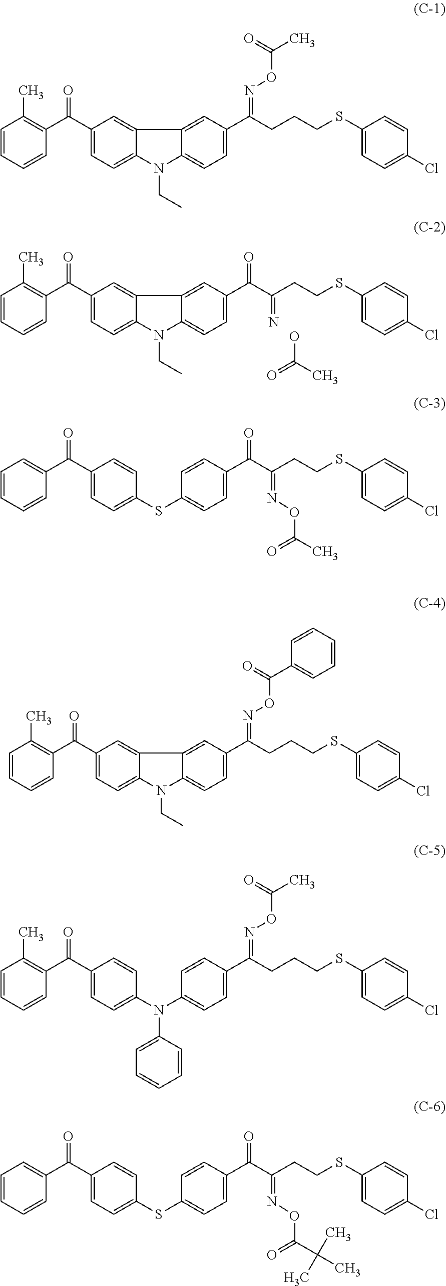

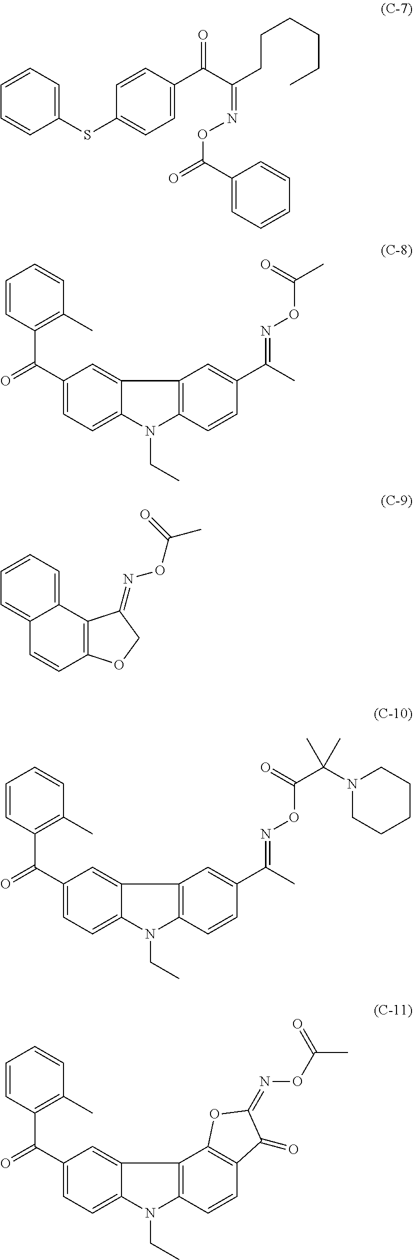

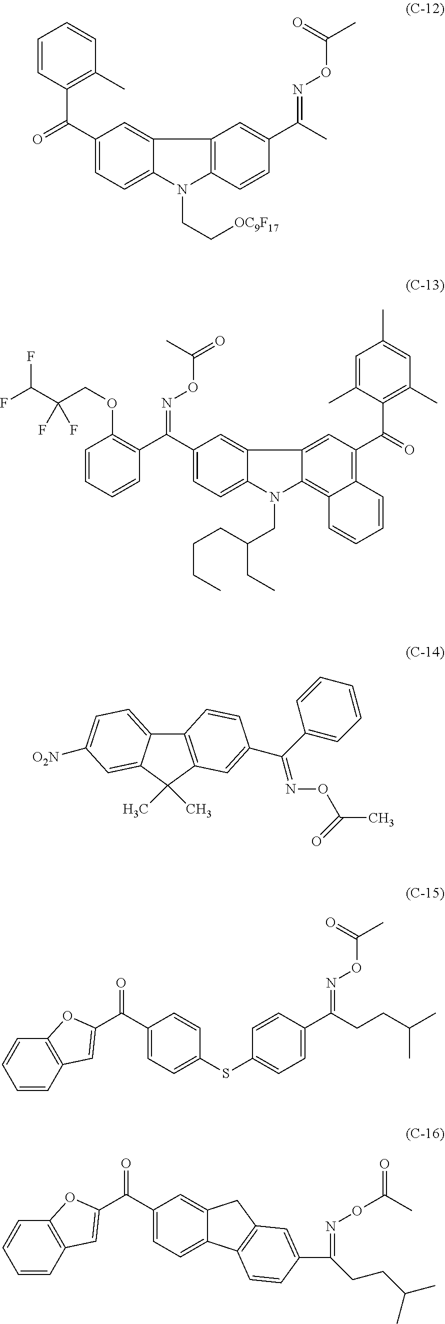

In the present invention, as the photoradical polymerization initiator, a photoradical polymerization initiator having two functional groups or three or more functional groups may be used. By using this photoradical polymerization initiator, two or more radicals are generated from one molecule of the photoradical polymerization initiator. Therefore, excellent sensitivity can be obtained. In addition, in a case where a compound having an asymmetric structure is used, crystallinity deteriorates, solubility in a solvent or the like is improved, precipitation is not likely to occur over time, and temporal stability of the photosensitive composition can be improved. Specific examples of the photoradical polymerization initiator having two functional groups or three or more functional groups include a dimer of an oxime compound described in JP2010-527339A, JP2011-524436A, WO2015/004565A, paragraphs “0407” to “0412” of JP2016-532675A, or paragraphs “0039” to “0055” of WO2017/033680A, a compound (E) and a compound (G) described in JP2013-522445A, Cmpd 1 to 7 described in WO2016/034963A, an oxime ester photoinitiator described in paragraph “0007” of JP2017-523465A, a photoradical polymerization initiator described in paragraphs “0020” to “0033” of JP2017-167399A, and a photopolymerization initiator (A) described in paragraphs “0017” to “0026” of JP2017-151342A.

In the present invention, a pinacol compound can also be used as the photoradical polymerization initiator. Examples of the pinacol compound include benzopinacol, 1,2-dimethoxy-1,1,2,2-tetraphenylethane, 1,2-diethoxy-1,1,2,2-tetraphenylethane, 1,2-diphenoxy-1,1,2,2-tetraphenylethane, 1,2-dimethoxy-1,1,2,2-tetra(4-methylphenyl)ethane, 1,2-diphenoxy-1,1,2,2-tetra(4-methoxyphenyl)ethane, 1,2-bis(trimethylsilloxy)-1,1,2,2-tetraphenylethane, 1,2-bis(triethylsilloxy)-1,1,2,2-tetraphenylethane, 1,2-bis(t-butyldimethylsilloxy)-1,1,2,2-tetraphenylethane, 1-hydroxy-2-trimethylsilloxy-1,1,2,2-tetraphenylethane, 1-hydroxy-2-triethylsilloxy-1,1,2,2-tetraphenylethane, and 1-hydroxy-2-t-butyldimethylsilloxy-1,1,2,2-tetraphenylethane. In addition, the details of the pinacol compound can be found in JP2014-523939A and JP2014-521772A, the contents of which are incorporated herein by reference.

In the present invention, it is preferable that the photoradical polymerization initiator includes a photoradical polymerization initiator b1 that satisfies the following condition 1.

Condition 1: after a propylene glycol monomethyl ether acetate solution including 0.035 mmol/L of the photoradical polymerization initiator b1 is exposed to pulses of light having a wavelength of 355 nm under conditions of a maximum instantaneous illuminance of 375000000 W/m², a pulse duration of 8 nanoseconds, and a frequency of 10 Hz, a quantum yield q₃₅₅ is 0.05 or higher.

The quantum yield q₃₅₅ of the photoradical polymerization initiator b1 is preferably 0.10 or higher, more preferably 0.15 or higher, still more preferably 0.25 or higher, still more preferably 0.35 or higher, and still more preferably 0.45 or higher.

In this specification, the quantum yield q₃₅₅ of the photoradical polymerization initiator b1 is a value obtained by dividing the number of decomposed molecules in the photoradical polymerization initiator b1 after the pulse exposure under the condition 1 by the number of absorbed photons in the photoradical polymerization initiator b1. Regarding the number of absorbed photons, the number of irradiated photons was obtained from the exposure time during the pulse exposure under the above-described condition, an average absorbance at 355 nm before and after exposure was converted into a transmittance, and the number of irradiated photons was multiplied by (1−transmittance) to obtain the number of absorbed photons. Regarding the number of decomposed molecules, a decomposition rate of the photoradical polymerization initiator b1 is obtained from the absorbance of the photoradical polymerization initiator b1 after exposure, and the decomposition rate is multiplied by the number of molecules present in the photoradical polymerization initiator b1 to obtain the number of decomposed molecules. In addition, regarding the absorbance of the photoradical polymerization initiator b1, a propylene glycol monomethyl ether acetate solution including 0.035 mmol/L of the photoradical polymerization initiator b1 is put into an optical cell of 1 cm×1 cm×4 cm, and the absorbance of the initiator b1 can be measured using a spectrophotometer. As the spectrophotometer, for example, HP8453 (manufactured by Agilent Technologies Inc.) can be used. Examples of the photoradical polymerization initiator b1 that satisfies the above-described condition 1 include IRGACURE-OXE01, OXE02, and OXE03 (all of which are manufactured by BASF SE). In addition, a compound having the following structure can be preferably used as the photoradical polymerization initiator b1 that satisfies the above-described condition 1. In particular, from the viewpoint of adhesiveness, IRGACURE-OXE01 and OXE02 are preferably used. In addition, from the viewpoint of curing properties, a compound represented by the following Formula (I3) is preferably used.

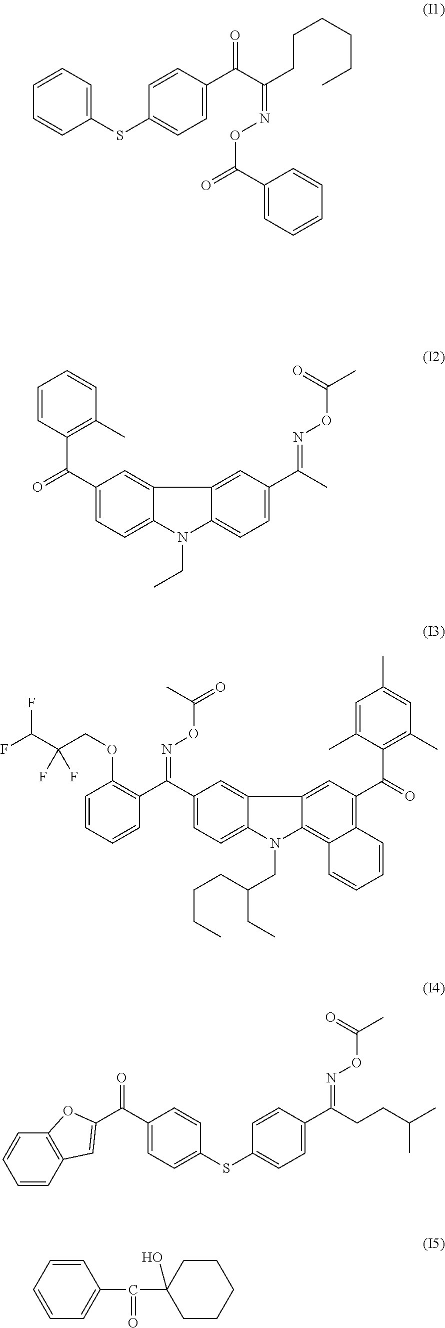 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\CCC(C)C)c1ccc(Sc2ccc(C(=O)c3cc4ccccc4o3)cc2)cc1 ; O=C(c1ccccc1)C1(O)CCCCC1]

In addition, it is more preferable that the photoradical polymerization initiator b1 further satisfies the following condition 2.

Condition 2: after a film having a thickness of 1.0 μm and including 5 mass % of the photoradical polymerization initiator b1 and 95 mass % of a resin is exposed to pulses of light having a wavelength of 265 nm under conditions of a maximum instantaneous illuminance of 375000000 W/m², a pulse duration of 8 nanoseconds, and a frequency of 10 Hz, a quantum yield q₂₆₅ is 0.05 or higher.

The quantum yield q₂₆₅ of the photoradical polymerization initiator b1 is preferably 0.10 or higher, more preferably 0.15 or higher, still more preferably 0.20 or higher.

In this specification, the quantum yield q₂₆₅ of the photoradical polymerization initiator b1 is a value obtained by dividing the number of decomposed molecules in the photoradical polymerization initiator b1 per 1 cm² of the film after the pulse exposure under the condition 2 by the number of absorbed photons in the photoradical polymerization initiator b1. Regarding the number of absorbed photons, the number of irradiated photons was obtained from the exposure time during the pulse exposure under the condition 2, and the number of irradiated photons per 1 cm² of the film was multiplied by (1−transmittance) to obtain the number of absorbed photons. Regarding the number of decomposed molecules in the photoradical polymerization initiator b1 per 1 cm² of the film after exposure, a decomposition rate of the photoradical polymerization initiator b1 is obtained from a change in the absorbance of the film before and after exposure is obtained, and the decomposition rate of the photoradical polymerization initiator b1 is multiplied by the number of molecules present in the photoradical polymerization initiator b1 per 1 cm² of the film. The weight of the film per 1 cm² of the film area is obtained by setting the film density as 1.2 g/cm³, and the number of molecules present in the photoradical polymerization initiator b1 per 1 cm² of the film is obtained as “((Weight of Film per 1 cm² of Film×5 mass % (Content of Photoradical Polymerization Initiator b1)/Molecular Weight of Photoradical Polymerization Initiator b1)×6.02×10²³ (Avogadro's Number)”.

In addition, it is preferable that the photoradical polymerization initiator b1 used in the present invention satisfies the following condition 3.

Condition 3: after a film including 5 mass % of the photoradical polymerization initiator b1 and a resin is exposed to one pulse of light having a wavelength in a wavelength range of 248 to 365 nm under conditions of a maximum instantaneous illuminance of 625000000 W/m², a pulse duration of 8 nanoseconds, and a frequency of 10 Hz, a radical concentration in the film reaches 0.000000001 mmol or higher per 1 cm² of the film.

The radical concentration in the film under the condition 3 per 1 cm² of the film reaches preferably 0.000000005 mmol or higher, more preferably 0.00000001 mmol or higher, still more preferably 0.00000003 mmol or higher, and still more preferably 0.0000001 mmol or higher.

In this specification, the radical concentration in the above-described film is obtained by multiplying a quantum yield of the photoradical polymerization initiator b1 with respect to the light having a measurement wavelength by (1−transmittance of film) to calculate a decomposition rate per number of incident photons and calculating the density of photoradical polymerization initiator b1 decomposed per 1 cm² of the film from “mol number of photons per one pulse”×“decomposition rate of the photoradical polymerization initiator b1 per number of incident photons”. The radical concentration is a value calculated assuming that the entirety of the photoradical polymerization initiator b1 decomposed by light irradiation is a radical (that does not disappear during an intermediate reaction).

The resin used for the measurement under the condition 2 or 3 is not particularly limited as long as it is compatible to the photoradical polymerization initiator b1. For example, a resin (A) having the following structure is preferably used. A numerical value added to a repeating unit represents a molar ratio, a weight-average molecular weight is 40000, and a dispersity (Mn/Mw) is 5.0.

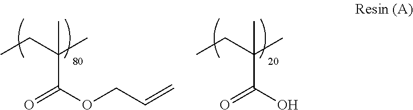

From the viewpoint of easily instantaneously generating a large amount of a radical by pulse exposure, as the photoradical polymerization initiator b1, an alkylphenone compound or an oxime compound is preferable, and an oxime compound is more preferable. In addition, it is preferable that the photoradical polymerization initiator b1 is a compound that is likely to cause two-photon absorption to occur. The two-photon absorption refers to an excitation process of simultaneously absorbing two photons.

The photoradical polymerization initiator used in the present invention may consist of only one photoradical polymerization initiator or may include two or more photoradical polymerization initiators. In a case where the photoradical polymerization initiator includes two or more photoradical polymerization initiators, each of the photoradical polymerization initiators may be the photoradical polymerization initiator b1 that satisfies the above-described condition 1. In addition, the photoradical polymerization initiator B may include one or more photoradical polymerization initiators b1 that satisfy the above-described condition 1 and one or more photoradical polymerization initiators b2 that do not satisfy the above-described condition 1. In a case where two or more photoradical polymerization initiators included in the photoradical polymerization initiator consist of the photoradical polymerization initiators b1 that satisfy the above-described condition 1, a required amount of a radical for curing the radically polymerizable compound can be easily instantaneously generated by pulse exposure. In a case where two or more photoradical polymerization initiators included in the photoradical polymerization initiator includes one or more photoradical polymerization initiators b1 that satisfy the above-described condition 1 and one or more photoradical polymerization initiators b2 that do not satisfy the above-described condition 1, desensitization over time caused by pulse exposure can be easily suppressed.

From the viewpoint of easily adjusting the sensitivity, it is preferable that the photoradical polymerization initiator used in the present invention include two or more photoradical polymerization initiators. In addition, in a case where the photoradical polymerization initiator used in the present invention includes two or more photoradical polymerization initiators, from the viewpoint of curing properties, it is preferable that the photoradical polymerization initiator satisfies the following condition 1a.

Condition 1a: after a propylene glycol monomethyl ether acetate solution including 0.035 mmol/L of a mixture is exposed to pulses of light having a wavelength of 355 nm under conditions of a maximum instantaneous illuminance of 375000000 W/m², a pulse duration of 8 nanoseconds, and a frequency of 10 Hz, a quantum yield q₃₅₅ is preferably 0.05 or higher, more preferably 0.10 or higher, still more preferably 0.15 or higher, still more preferably 0.25 or higher, still more preferably 0.35 or higher, and still more preferably 0.45 or higher, the mixture being obtained by mixing two or more photoradical polymerization initiators at a ratio at which the photosensitive composition includes the two or more photoradical polymerization initiators.

In addition, in a case where the photoradical polymerization initiator used in the present invention includes two or more photoradical polymerization initiators, from the viewpoint of curing properties, it is preferable that the photoradical polymerization initiator satisfies the following condition 2a.

Condition 2a: after a film having a thickness of 1.0 μm and including 5 mass % of a mixture and 95 mass % of a resin is exposed to pulses of light having a wavelength of 265 nm under conditions of a maximum instantaneous illuminance of 375000000 W/m², a pulse duration of 8 nanoseconds, and a frequency of 10 Hz, a quantum yield q₂₆₅ is 0.05 or higher, more preferably 0.10 or higher, still more preferably 0.15 or higher, and still more preferably 0.20 or higher, the mixture being obtained by mixing two or more photoradical polymerization initiators at a ratio at which the photosensitive composition includes the two or more photoradical polymerization initiators.

In addition, in a case where the photoradical polymerization initiator used in the present invention includes two or more photoradical polymerization initiators, from the viewpoint of curing properties, it is preferable that the photoradical polymerization initiator satisfies the following condition 3a.

Condition 3a: after a film including 5 mass % of a mixture and a resin is exposed to pulses of light having a wavelength in a wavelength range of 248 to 365 nm for 0.1 seconds under conditions of a maximum instantaneous illuminance of 625000000 W/m², a pulse duration of 8 nanoseconds, and a frequency of 10 Hz, a radical concentration in the film reaches preferably 0.000000001 mmol or higher, more preferably 0.000000005 mmol or higher, still more preferably 0.00000001 mmol or higher, still more preferably 0.00000003 mmol or higher, and most preferably 0.0000001 mmol or higher per 1 cm² of the film, the mixture being obtained by mixing two or more photoradical polymerization initiators at a ratio at which the photosensitive composition includes the two or more photoradical polymerization initiators.

The content of the photoradical polymerization initiator is preferably 15 mass % or lower, more preferably 10 mass % or lower, and still more preferably 7 mass % or lower with respect to the total solid content of the photosensitive composition. The lower limit is preferably 1 mass % or higher, more preferably 2 mass % or higher, and still more preferably 3 mass % or higher. In addition, from the viewpoint of curing properties, the content of the photoradical polymerization initiator is preferably 10 to 200 parts by mass with respect to 100 parts by mass of the radically polymerizable compound. The upper limit is preferably 100 parts by mass or less and more preferably 50 parts by mass or less. The lower limit is preferably 20 parts by mass or more and more preferably 30 parts by mass or more. In a case where the photosensitive composition according to the embodiment of the present invention includes two or more photoradical polymerization initiators, it is preferable that the total content of the two or more photoradical polymerization initiators B is in the above-described range.

In addition, the content of the photoradical polymerization initiator b1 is preferably 15 mass % or lower, more preferably 10 mass % or lower, and still more preferably 7 mass % or lower with respect to the total solid content of the photosensitive composition. The lower limit is preferably 1 mass % or higher, more preferably 2 mass % or higher, and still more preferably 3 mass % or higher. In addition, from the viewpoint of curing properties, the content of the photoradical polymerization initiator b1 is preferably 10 to 200 parts by mass with respect to 100 parts by mass of the radically polymerizable compound. The upper limit is preferably 100 parts by mass or less and more preferably 50 parts by mass or less. The lower limit is preferably 20 parts by mass or more and more preferably 30 parts by mass or more. In a case where the photosensitive composition according to the embodiment of the present invention includes two or more photoradical polymerization initiators b1, it is preferable that the total content of the two or more photoradical polymerization initiators b1 is in the above-described range.

<<Chain Transfer Agent, Radical Trapping Agent>>

The photosensitive composition according to the embodiment of the present invention includes at least one selected from a chain transfer agent or a radical trapping agent.

As described above, in a case where the photosensitive composition according to the embodiment of the present invention includes the radical trapping agent, the line width of the obtained pattern can be reduced. By increasing the mixing amount of the radical trapping agent, the line width of the obtained pattern can be further reduced. In addition, in a case where the photosensitive composition according to the embodiment of the present invention includes the chain transfer agent, the line width of the obtained pattern can be increased. By increasing the mixing amount of the chain transfer agent, the line width of the obtained pattern can be further increased.

(Chain Transfer Agent)

First, the chain transfer agent used for the photosensitive composition according to the embodiment of the present invention will be described. Examples of the chain transfer agent include a thiol compound, a thiocarbonylthio compound, and an aromatic α-methyl alkenyl dimer. A thiol compound is preferable from the viewpoint of easily adjusting the line width of a pattern with a small mixing amount of the thiol compound. In addition, it is preferable that the chain transfer agent is a compound having a small colored area.

[Thiol Compound]

The thiol compound is a compound having one or more thiol groups and preferably a compound having two or more thiol groups. The upper limit of the number of thiol groups in the thiol compound is preferably 20 or less, more preferably 15 or less, still more preferably 10 or less, still more preferably 8 or less, and still more preferably 6 or less. The lower limit of the number of thiol groups in the thiol compound is preferably 3 or more. From the viewpoint of easily obtaining higher effects of the present invention, it is more preferable that the thiol compound is a compound having four or more thiol groups.

In addition, it is also preferable that the thiol compound is a compound derived from a polyfunctional alcohol.

It is preferable that the thiol compound is a compound represented by the following Formula (SH-1).

L¹-(SH)ₙ Formula (SH-1)

(In the formula, SH represents a thiol group, L¹ represents an n-valent group, and n represents an integer of 1 or more)

Examples of the n-valent group represented by L¹ in Formula (SH-1) include a hydrocarbon group, a heterocyclic group, —O—, —S—, —NR—, —CO—, —COO—, —OCO—, —SO₂—, and a group consisting of a combination of the above-described groups. R represents a hydrogen atom, an alkyl group, or an aryl group and preferably a hydrogen atom. The hydrocarbon group may be an aliphatic hydrocarbon group or an aromatic hydrocarbon group. In addition, the aliphatic hydrocarbon group may be cyclic or acyclic. In addition, the aliphatic hydrocarbon group may be a saturated aliphatic hydrocarbon group or an unsaturated aliphatic hydrocarbon group. The hydrocarbon group may have a substituent or may be unsubstituted. In addition, the cyclic aliphatic hydrocarbon group and the aromatic hydrocarbon group may be a monocycle or a fused ring. The heterocyclic group may be a monocycle or a fused ring. It is preferable that the heterocyclic group is a 5- or 6-membered ring. The heterocyclic group may be an aliphatic heterocyclic group or an aromatic heterocyclic group. In addition, examples of the heteroatom constituting the heterocyclic group include a nitrogen atom, an oxygen atom, and a sulfur atom. The number of carbon atoms constituting L¹ is preferably 3 to 100 and more preferably 6 to 50.

In Formula (SH-1), n represents an integer of 1 or more. The upper limit of n is preferably 20 or less, more preferably 15 or less, still more preferably 10 or less, still more preferably 8 or less, and still more preferably 6 or less. The lower limit of n is preferably 2 or more and more preferably 3 or more. It is still more preferable that n represents 4.

Specific examples of the thiol compound include a compound having the following structure. In addition, examples of a commercially available product of the thiol compound include PEMP (a thiol compound, manufactured by SC Organic Chemical Co., Ltd.), SANCELER M (a thiol compound, manufactured by Sanshin Chemical Industry Co., Ltd.), and KARENZ MT BD1 (a thiol compound, manufactured by Showa Denko K.K.).

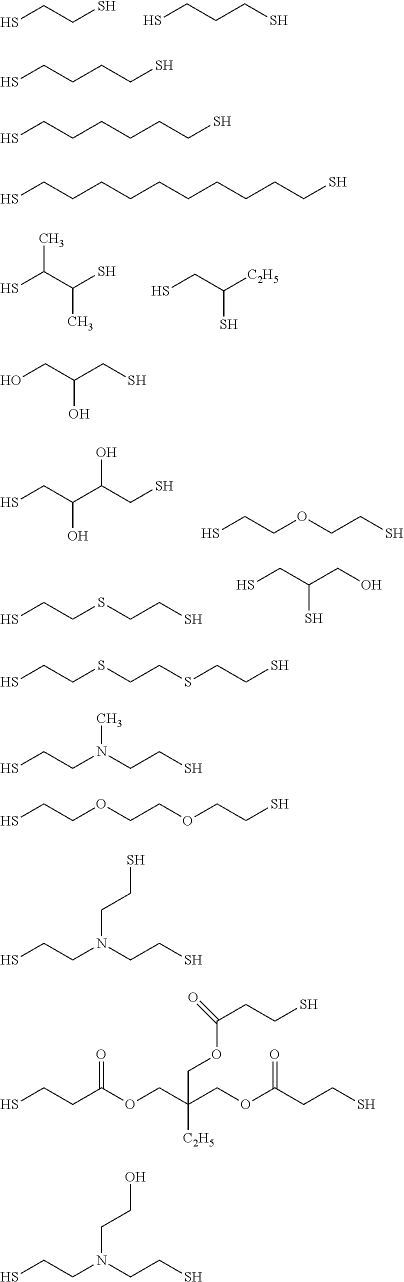

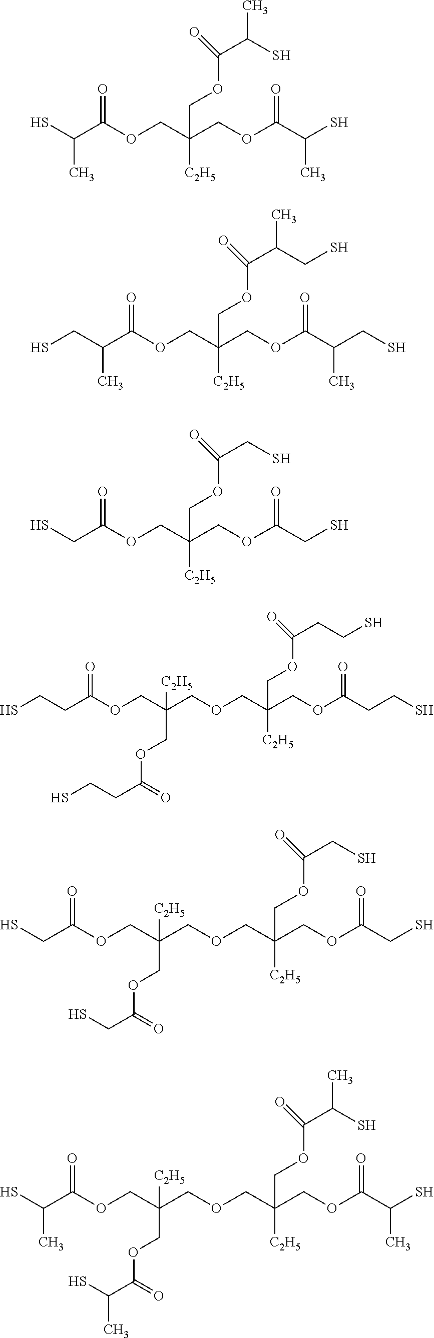 [SMILES: CCC(COC(=O)C(C)S)(COC(=O)C(C)S)COC(=O)C(C)S ; CCC(COC(=O)C(C)CS)(COC(=O)C(C)CS)COC(=O)C(C)CS ; CCC(COC(=O)CS)(COC(=O)CS)COC(=O)CS ; CCC(COCC(CC)(COC(=O)CCS)COC(=O)CCS)(COC(=O)CCS)COC(=O)CCS ; CCC(COCC(CC)(COC(=O)CS)COC(=O)CS)(COC(=O)CS)COC(=O)CS ; CCC(COCC(CC)(COC(=O)C(C)S)COC(=O)C(C)S)(COC(=O)C(C)S)COC(=O)C(C)S]

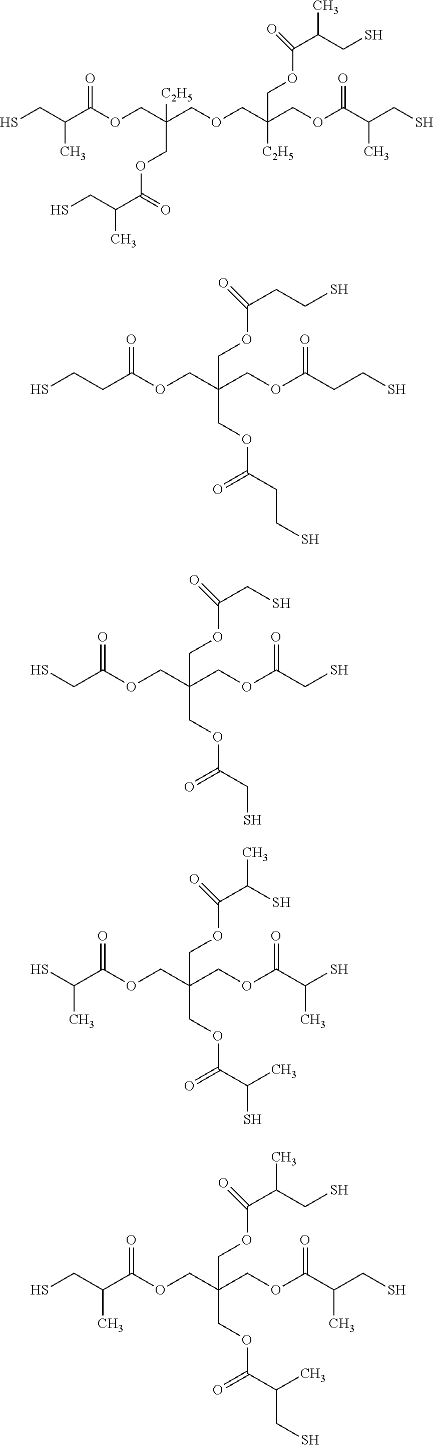

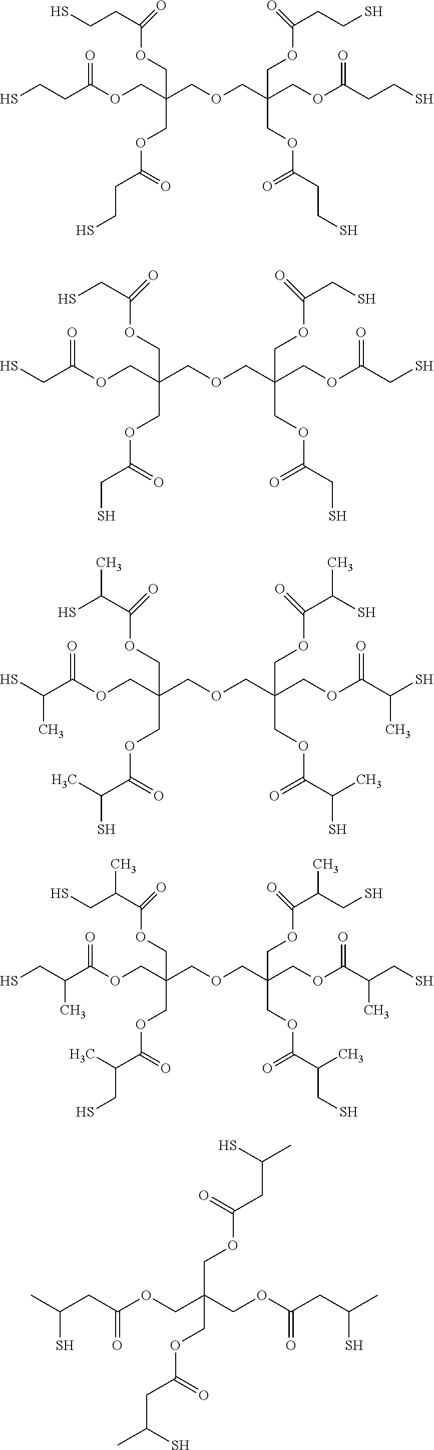

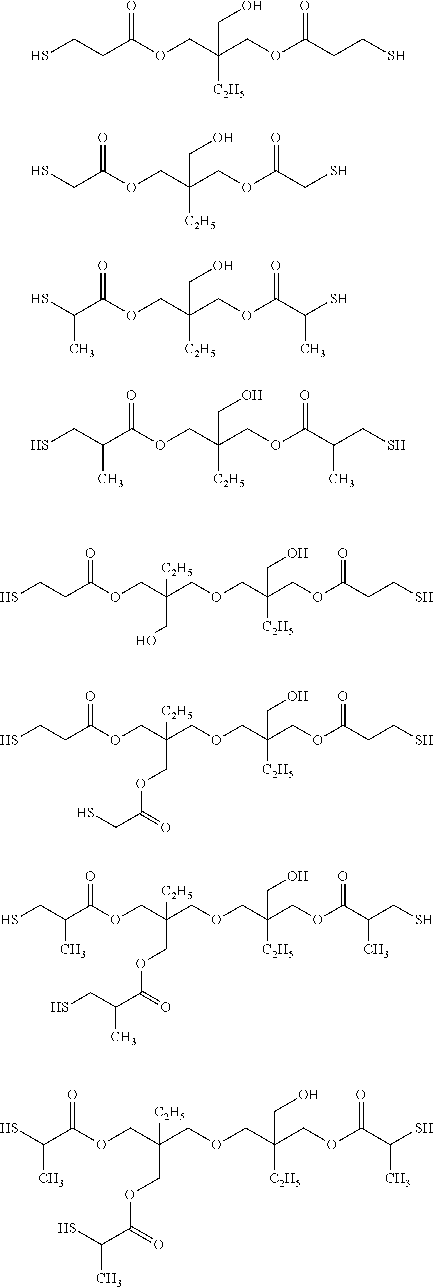

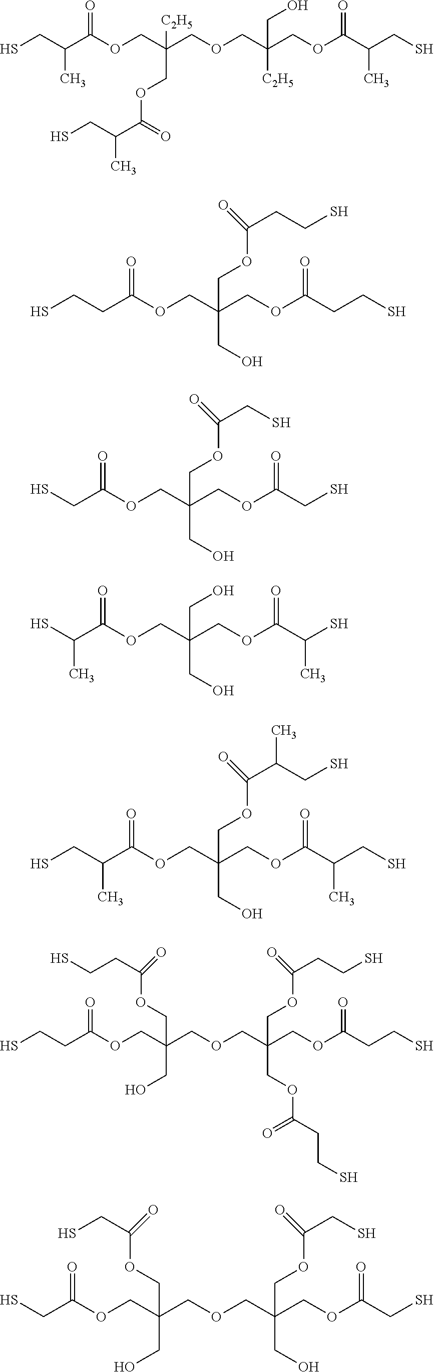

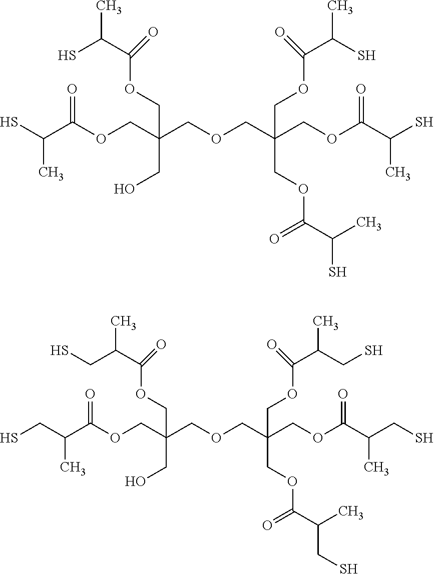 [SMILES: CC(S)C(=O)OCC(CO)(COCC(COC(=O)C(C)S)(COC(=O)C(C)S)COC(=O)C(C)S)COC(=O)C(C)S ; CC(CS)C(=O)OCC(CO)(COCC(COC(=O)C(C)CS)(COC(=O)C(C)CS)COC(=O)C(C)CS)COC(=O)C(C)CS]

[Thiocarbonylthio Compound]

The thiocarbonylthio compound is a compound having a thiocarbonylthio group (—S—C(═S)—) in the molecule, and examples thereof include a bis(thiocarbonyl)disulfide compound (compound represented by the following Formula (SC-1)), a dithioester compound (compound represented by the following Formula (SC-2)), a trithiocarbonate compound (compound represented by the following Formula (SC-3)), a dithiocarbamate compound (compound represented by the following Formula (SC-4)), and a xanthate compound (compound represented by the following Formula (SC-5)).

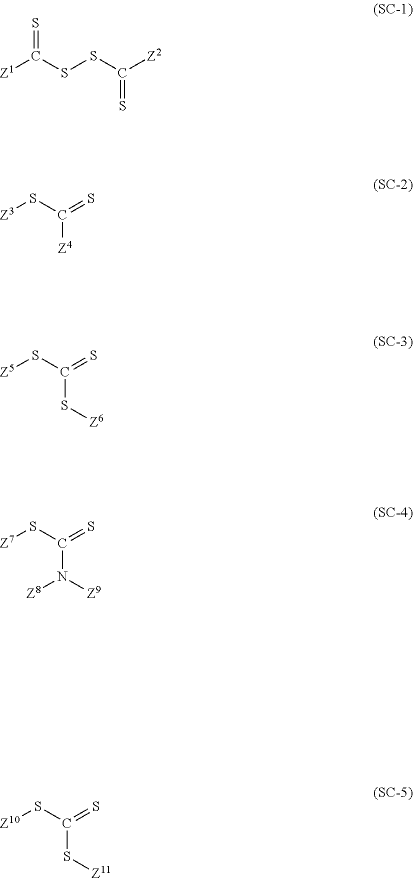

In Formulae (SC-1) to (SC-5), Z¹ to Z¹¹ each independently represent a substituent.

Examples of the substituent represented by Z¹ to Z¹¹ include an alkyl group, an aryl group, a heteroaryl group, —SR^{Z1}—, —NR^{Z1}R^{Z2}, —NR^{Z1}—NR^{Z2}R^{Z3}, —COOR^{Z1}, —COOR^{Z1}, —OCOR^{Z1}, —CONR^{Z1}R^{Z2}, —P(═O)(OR^{Z1})₂, and —O—P(═O)R^{Z1}R^{Z2} (where R^{Z1}, R^{Z2}, and R^{Z3} each independently represent an alkyl group, an aryl group, or a heteroaryl group). In addition, among the groups, one or more hydrogen atoms bonded to a carbon atom may be substituted with a cyano group, a carboxyl group, or the like.

The number of carbon atoms in the alkyl group is preferably 1 to 30, more preferably 1 to 15, and still more preferably 1 to 8. The alkyl group may be linear, branched, or cyclic and is preferably linear or branched.

The number of carbon atoms in the aryl group is preferably 6 to 30, more preferably 6 to 20, and still more preferably 6 to 12.

The heteroaryl group is preferably a monocyclic or fused heteroaryl group including 2 to 8 rings, and more preferably a monocyclic or fused heteroaryl group including 2 to 4 rings. The number of heteroatoms forming the ring of the heteroaryl group is preferably 1 to 3. It is preferable that the heteroatoms forming the ring of the heteroaryl group are a nitrogen atom, an oxygen atom, or a sulfur atom. It is preferable that the heteroaryl group is a 5- or 6-membered ring. The number of carbon atoms forming the ring of the heteroaryl group is preferably 3 to 30, more preferably 3 to 18, and still more preferably 3 to 12.

Specific examples of the bis(thiocarbonyl)disulfide compound include tetrabutylthiuram disulfide, tetramethylthiuram disulfide, bis(n-octylmercapto-thiocarbonyl)disulfide, bis(n-dodecylmercapto-thiocarbonyl)disulfide, bis(benzylmercapto-thiocarbonyl)disulfide, bis(n-butylmercapto-thiocarbonyl)disulfide, bis(t-butylmercapto-thiocarbonyl)disulfide, bis(n-heptylmercapto-thiocarbonyl)disulfide, bis(n-hexylmercapto-thiocarbonyl)disulfide, bis(n-pentylmercapto-thiocarbonyl)disulfide, bis(n-nonylmercapto-thiocarbonyl)disulfide, bis(n-decylmercapto-thiocarbonyl)disulfide, bis(t-dodecylmercapto-thiocarbonyl)disulfide, bis(n-tetradecylmercapto-thiocarbonyl)disulfide, bis(n-hexadecylmercapto-thiocarbonyl)disulfide, and bis(n-octadecylmercapto-thiocarbonyl)disulfide.

Specific examples of the dithioester compound include 2-phenyl-2-propyl benzothioate, 4-cyano-4-(phenylthiocarbonylthio)pentanoic acid, and 2-cyano-2-propyl benzodithioate.

Specific examples of the trithiocarbonate compound include S-(2-cyano-2-propyl)-S-dodecyltrithiocarbonate, 4-cyano-4-[(dodecylsulfanyl-thiocarbonyl)sulfanyl]pentanoic acid, cyanomethyl dodecyl trithiocarbonate, and 2-(dodecylthiocarbonothioylthio)-2-methylpropionic acid.

Specific examples of the dithiocarbamate compound include cyanomethyl methyl(phenyl)carbamodithioate, and cyanomethyl diphenylcarbamodithioate.

Specific examples of the xanthate compound include xanthic acid ester.

[Aromatic A-Methyl Alkenyl Dimer]

Examples of the aromatic α-methyl alkenyl dimer include 2,4-diphenyl-4-methyl-1-pentene.

From the viewpoint that device contamination caused by sublimation can be suppressed, the molecular weight of the chain transfer agent is preferably 200 or higher. From the viewpoint that the SH valence per weight can be increased, the upper limit is preferably 1000 or lower, more preferably 800 or lower, and still more preferably 600 or lower.

(Radical Trapping Agent)

Next, the radical trapping agent used for the photosensitive composition according to the embodiment of the present invention will be described. Examples of the radical trapping agent include a naphthalene derivative, a thioether compound, a hindered phenol compound, a hindered amine compound, an N-oxyl compound, a hydrazyl compound, and a verdazyl compound. Among these, a hindered phenol compound, a hindered amine compound, an N-oxyl compound, a hydrazyl compound, or a verdazyl compound is preferable. In addition, from the viewpoint of controlling the amount of a radical generated from the photoradical polymerization initiator in the photosensitive composition during exposure to adjust the sensitivity of the photosensitive composition, it is preferable that the radical trapping agent is a compound that quantitatively react with the radical. From this viewpoint, it is preferable that the radical trapping agent is an N-oxyl compound or a hydrazyl compound. In addition, from the viewpoint of radical trapping performance, an N-oxyl compound is preferably used. In addition, from the viewpoint of easy control of sensitivity adjustment, a hydrazyl compound is preferably used. In addition, it is preferable that the radical trapping agent is a compound having a small colored area.

[Naphthalene Derivative]

Examples of the naphthalene derivative include a naphthohydroquinone compound such as a naphthohydroquinone sulfonate onium salt. Specific examples of the naphthalene derivative include 1,4-dihydroxynaphthalene, 6-amino-2,3-dihydro-5,8-dihydroxynaphthalene-1,4-dione, 6-methylamino-2,3-dihydro-5,8-dihydroxynaphthalene-1,4-dione, 6-ethylamino-2,3-dihydro-5,8-dihydroxynaphthalene-1,4-dione, 6-propylamino-2,3-dihydro-5,8-dihydroxynaphthalene-1,4-dione, 6-butylamino-2,3-dihydro-5,8-dihydroxynaphthalene-1,4-dione, 2-(α,α-dimethyl)naphthalene, 2-(α,α-dimethylbenzyl)naphthalene, 2-t-amylnaphthalene, and 2-trimethylsilyl-1,4,5,8-dimethyl-1,2,3,4,4a,5,8,8a-octahydronaphthalene. Among these, 1,4-dihydroxynaphthalene is more preferable.

[Thioether Compound]

The thioether compound is not particularly limited as long as it is a compound having at least one thioether group in a molecule. Examples of the thioether compound include dimethyl 3,3′-thiodipropionate, dihexyl thiodipropionate, dinonyl thiodipropionate, didecyl thiodipropionate, diundecyl thiodipropionate, didodecyl thiodipropionate, ditridecyl thiodipropionate, ditetradecyl thiodipropionate, dipentadecyl thiodipropionate, hexadecyl thiodipropionate, diheptadecyl thiodipropionate, dioctadecyl thiodipropionate, dihexyl thiodibutyrate, dinonyl thiodibutyrate, didecyl thiodibutyrate, diundecyl thiodibutyrate, didodecyl thiodibutyrate, ditridecyl thiodibutyrate, ditetradecyl thiodibutyrate, dipentadecyl thiodibutyrate, hexadecyl thiodibutyrate, 3-methoxy-2-[2-[cyclopropyl (3-flurophenylimino)methylthiomethyl]phenyl]acrylic acid methyl ester, and diheptadecyl thiodibutyrate. Among these, dimethyl 3,3′-thiodipropionate is more preferable.

[Hindered Amine Compound]

Examples of the hindered amine compound include a compound having a partial structure represented by the following Formula (HA1).

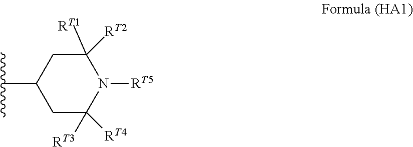

In the formula, a wave line represents a direct bond. R^{T1} to R^{T4} each independently represent a hydrogen atom or an alkyl group, and R^{T5} represents an alkyl group, an alkoxy group, an aryloxy group, or an oxygen radical.

As the alkyl group, a linear alkyl group having 1 to 3 carbon atoms is preferable, and a methyl group is more preferable. As the alkoxy group, a linear alkoxy group having 1 to 4 carbon atoms is preferable.

The molecular weight of the hindered amine compound is preferably 2000 or lower and more preferably 1000 or lower. Examples of a commercially available product of the hindered amine compound include ADEKA STAB LA-52, LA-57, LA-72, LA-77Y, LA-77G, LA-81, LA-82, LA-87, LA-402AF, and LA-502XP (manufactured by Adeka Corporation) and TINUVIN 765, TINUVIN 770 DF, TINUVIN XT 55 FB, TINUVIN 111 FDL, TINUVIN 783 FDL, TINUVIN 791 FB, TINUVIN 123, TINUVIN 144, and TINUVIN 152 (manufactured by BASF SE).

[Hindered Phenol Compound]

Examples of the hindered phenol compound include a compound having a structure represented by the following Formula (HP1).

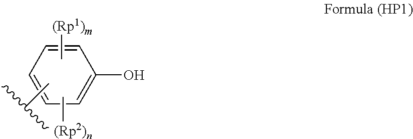

In the formula, a wave line represents a direct bond, Rp¹ represents an alkyl group having 3 or more carbon atoms, Rpt represents a substituent, m represents an integer of 1 or more, n represents an integer of 0 or more, and m+n is 4 or less.

Specific examples of the hindered phenol compound include 4-tert-butylcatechol, 4,4′-thiobis(3-methyl-6-t-butyl phenol), 2,2′-methylenebis(4-methyl-6-t-butylphenol), and pentaerythritol tetrakis [3-(3,5-di-tert-butyl-4-hydroxyphenyl)propionate]. Examples of a commercially available product of the hindered phenol compound include ADEKA STAB AO-20, ADEKA STAB AO-30, ADEKA STAB AO-40, ADEKA STAB AO-50, ADEKA STAB AO-50F, ADEKA STAB AO-60, ADEKA STAB AO-60G; ADEKA STAB AO-80, and ADEKA STAB AO-330 (all of which are manufactured by Adeka Corporation).

[N-Oxyl Compound]

The N-oxyl compound is not particularly limited as long as it is a compound having an N-oxyl group, and a well-known compound can be used. Examples of the N-oxyl compound include a piperidine 1-oxyl compound and a pyrrolidine 1-oxyl compound. Examples of the piperidine-1-oxyl compound include piperidine-1-oxyl, 2,2,6,6-tetramethylpiperidine 1-oxyl, 4-oxo-2,2,6,6-tetramethylpiperidine 1-oxyl, 4-hydroxy-2,2,6,6-tetramethylpiperidine 1-oxyl, 4-acetamido-2,2,6,6-tetramethylpiperidine 1-oxyl, 4-maleimido-2,2,6,6-tetramethylpiperidine 1-oxyl, and 4-phosphonooxy-2,2,6,6-tetramethylpiperidine-1-oxyl. Examples of the pyrrolidine 1-oxyl compound include 3-carboxyproxyl and 3-carboxy-2,2,5,5-tetramethylpyrrolidine 1-oxyl.

[Hydrazyl Compound]

The hydrazyl compound is not particularly limited as long as it is a compound having a hydrazyl group, and a well-known compound can be used. Examples of the hydrazyl compound include 2,2-diphenyl-1-picrylhydrazyl and 2,2-di(4-tert-octylphenyl)-1-picrylhydrazyl.

[Verdazyl Compound]

The verdazyl compound is not particularly limited as long as it is a compound having a verdazyl group, and a well-known compound can be used. Examples of the verdazyl compound include triphenylverdazyl.

In a case where the photosensitive composition according to the embodiment of the present invention includes the chain transfer agent, the content of the chain transfer agent is preferably 0.01% to 10 mass % with respect to the total solid content of the photosensitive composition. The upper limit is preferably 9 mass % or lower, more preferably 8 mass % or lower, and still more preferably 7 mass % or lower. The lower limit is preferably 0.02 mass % or higher, more preferably 0.05 mass % or higher, and still more preferably 0.1 mass % or higher.

In addition, the content of the chain transfer agent is preferably 0.1 to 100 parts by mass with respect to 100 parts by mass of the radically polymerizable compound. The upper limit is preferably 20 parts by mass or less and more preferably 10 parts by mass or less. The lower limit is preferably 0.5 parts by mass or more and more preferably 1 part by mass or more.

In addition, the content of the chain transfer agent is preferably 0.2 to 200 parts by mass with respect to 100 parts by mass of the photoradical polymerization initiator. The upper limit is preferably 100 parts by mass or less, more preferably 50 parts by mass or less, and still more preferably 20 parts by mass or less. The lower limit is preferably 1 part by mass or more, more preferably 1.5 parts by mass or more, and still more preferably 2 parts by mass or more.

In a case where the photosensitive composition according to the embodiment of the present invention includes the radical trapping agent, the content of the radical trapping agent is preferably 0.01% to 10.0 mass % with respect to the total solid content of the photosensitive composition. The upper limit is preferably 9 mass % or lower, more preferably 8 mass % or lower, and still more preferably 7 mass % or lower. The lower limit is preferably 0.02 mass % or higher, more preferably 0.05 mass % or higher, and still more preferably 0.1 mass % or higher.

In addition, the content of the radical trapping agent is preferably 0.1 to 100 parts by mass with respect to 100 parts by mass of the radically polymerizable compound. The upper limit is preferably 20 parts by mass or less and more preferably 10 parts by mass or less. The lower limit is preferably 0.5 parts by mass or more and more preferably 1 part by mass or more.

In addition, the content of the radical trapping agent is preferably 0.2 to 200 parts by mass with respect to 100 parts by mass of the photoradical polymerization initiator. The upper limit is preferably 100 parts by mass or less, more preferably 50 parts by mass or less, and still more preferably 20 parts by mass or less. The lower limit is preferably 1 part by mass or more, more preferably 1.5 parts by mass or more, and still more preferably 2 parts by mass or more.

In a case where the photosensitive composition according to the embodiment of the present invention includes the radical trapping agent, the content of the radical trapping agent is preferably 300 to 10 parts by mass with respect to 100 parts by mass of the chain transfer agent. The upper limit is preferably 250 parts by mass or less and more preferably 200 parts by mass or less. The lower limit is preferably 20 parts by mass or more and more preferably 30 parts by mass or more.

In addition, the total content of the chain transfer agent and the radical trapping agent is preferably 0.01% to 10.0 mass % with respect to the total solid content of the photosensitive composition. The upper limit is preferably 9 mass % or lower, more preferably 8 mass % or lower, and still more preferably 7 mass % or lower. The lower limit is preferably 0.02 mass % or higher, more preferably 0.05 mass % or higher, and still more preferably 0.1 mass % or higher.

In addition, the total content of the chain transfer agent and the radical trapping agent is preferably 0.1 to 100 parts by mass with respect to 100 parts by mass of the radically polymerizable compound. The upper limit is preferably 20 parts by mass or less and more preferably 10 parts by mass or less. The lower limit is preferably 0.5 parts by mass or more and more preferably 1 part by mass or more.

In addition, the total content of the chain transfer agent and the radical trapping agent is preferably 0.2 to 200 parts by mass with respect to 100 parts by mass of the photoradical polymerization initiator. The upper limit is preferably 100 parts by mass or less, more preferably 50 parts by mass or less, and still more preferably 20 parts by mass or less. The lower limit is preferably 1 part by mass or more, more preferably 1.5 parts by mass or more, and still more preferably 2 parts by mass or more.

<<Coloring Material>>

It is preferable that the photosensitive composition according to the embodiment of the present invention includes the coloring material. Examples of the coloring material include a chromatic colorant, a black colorant, and an infrared absorbing colorant. It is preferable that the coloring material used in the photosensitive composition according to the embodiment of the present invention includes at least a chromatic colorant.

(Chromatic Colorant)

Examples of the chromatic colorant include a red colorant, a green colorant, a blue colorant, a yellow colorant, a violet colorant, and an orange colorant. As the chromatic colorant, a pigment or a dye may be used. It is preferable that the chromatic colorant is a pigment. An average particle size (r) of the pigment satisfies preferably 20 nm≤r≤300 nm, more preferably 25 nm≤r≤250 nm, and still more preferably 30 nm≤r≤200 nm. “Average particle size” described herein denotes the average particle size of secondary particles which are aggregates of primary particles of the pigment. In addition, regarding a particle size distribution of the secondary particles of the pigment (hereinafter, simply referred to as “particle size distribution”) which can be used, secondary particles having a particle size of (average particle size±100) nm account for preferably 70 mass % or higher and more preferably 80 mass % or higher in the pigment.

As the pigment, an organic pigment is preferable. Preferable examples of the organic pigment are as follows:

Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments);

C.I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C.I. Pigment Green 7, 10, 36, 37, 58, 59, 62, and 63 (all of which are green pigments);

C.I. Pigment Violet 1, 19, 23, 27, 32, 37, and 42 (all of which are violet pigments); and

C.I. Pigment Blue 1, 2, 15, 15:1, 15:2, 15:3, 15:4, 15:6, 16, 22, 60, 64, 66, 79, and 80 (all of which are blue pigments).

Among these organic pigments, one kind may be used alone, or two or more kinds may be used in combination.

In addition, as the yellow pigment, a metal azo pigment including at least one anion selected from an azo compound represented by the following Formula (I) or an azo compound having a tautomeric structure of the azo compound represented by Formula (I), two or more metal ions, and a melamine compound can be used.

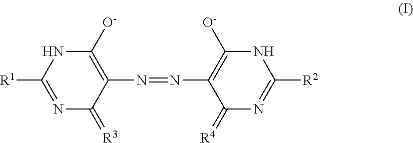

In the formula, R¹ and R² each independently represent OH or NR⁵R⁶, R³ and R⁴ each independently represent=O or ═NR⁷, and R⁵ to R⁷ each independently represent a hydrogen atom or an alkyl group. The number of carbon atoms in the alkyl group represented by R⁵ to R⁷ is preferably 1 to 10, more preferably 1 to 6, and still more preferably 1 to 4. The alkyl group may be linear, branched, or cyclic and is preferably linear or branched and more preferably linear. The alkyl group may have a substituent. As the substituent, a halogen atom, a hydroxy group, an alkoxy group, a cyano group, or an amino group is preferable.

In Formula (I), it is preferable that R¹ and R² represent OH. In addition, it is preferable that R³ and R⁴ represent O.

It is preferable that the melamine compound in the metal azo pigment is a compound represented by the following Formula (II).

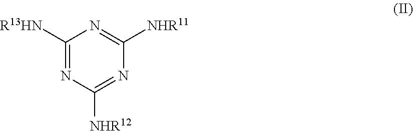

In the formula, R¹¹ to R¹³ each independently represent a hydrogen atom or an alkyl group. The number of carbon atoms in the alkyl group is preferably 1 to 10, more preferably 1 to 6, and still more preferably 1 to 4. The alkyl group may be linear, branched, or cyclic and is preferably linear or branched and more preferably linear. The alkyl group may have a substituent. As the substituent, a hydroxy group is preferable. It is preferable that at least one of R¹¹, . . . , or R¹³ represents a hydrogen atom, and it is more preferable that all of R¹¹ to R¹³ represent a hydrogen atom.

It is preferable that the above-described metal azo pigment is a metal azo pigment according to an aspect including at least one anion selected from an azo compound represented by Formula (I) or an azo compound having a tautomeric structure of the azo compound represented by Formula (I), metal ions including at least Zn²⁺ and Cu²⁺, and a melamine compound. In this aspect, the total content of Zn²⁺ and Cu²⁺ is preferably 95 to 100 mol %, more preferably 98 to 100 mol %, still more preferably 99.9 to 100 mol %, and still more preferably 100 mol % with respect to 1 mol of all the metal ions of the metal azo pigment. In addition, a molar ratio Zn²⁺:Cu²⁺ of Zn²⁺ to Cu²⁺ in the metal azo pigment is preferably 199:1 to 1:15, more preferably 19:1 to 1:1, and still more preferably 9:1 to 2:1. In addition, in this aspect, the metal azo pigment may further include a divalent or trivalent metal ion (hereinafter, also referred to as “metal ion Me1”) in addition to Zn²⁺ and Cu²⁺. Examples of the metal ion Me1 include Ni²⁺, Al³⁺, Fe²⁺, Fe³⁺, Co²⁺, Co³⁺, La³⁺, Ce³⁺, Pr³⁺, Nd²⁺, Nd³⁺, Sm²⁺, Sm³⁺, Eu²⁺, Eu³⁺, Gd³⁺, Tb³⁺, Dy³⁺, Ho³⁺, Yb²⁺, Yb³⁺, Er³⁺, Tm³⁺, Mg²⁺, Ca²⁺, Sr²⁺, Mn²⁺, Y³⁺, Sc³⁺, Ti²⁺, Ti³⁺, Nb³⁺, Mo²⁺, Mo³⁺, V²⁺, V³⁺, Zr²⁺, Zr³⁺, Cd²⁺, Cr³⁺, Pb²⁺, and Ba²⁺. Among these, at least one selected from Al³⁺, Fe²⁺, Fe³⁺, Co²⁺, Co³⁺, La³⁺, Ce³⁺, Pr³⁺, Nd³⁺, Sm³⁺, Eu³⁺, Gd³⁺, Tb³⁺, Dy³⁺, Ho³⁺, Yb³⁺, Er³⁺, Tm³⁺, Mg²⁺, Ca²⁺, Sr²⁺, Mn²⁺, or Y³⁺ is preferable, at least one selected from Al³⁺, Fe²⁺, Fe³⁺, Co²⁺, Co³⁺, La³⁺, Ce³⁺, Pr³⁺, Nd³⁺, Sm³⁺, Tb³⁺, Ho³⁺, or Sr²⁺ is more preferable, and at least one selected from Al³⁻, Fe²⁺, Fe³⁺, Co²⁺, or Co³⁺ is still more preferable. The content of the metal ion Me1 is preferably 5 mol % or lower, more preferably 2 mol % or lower, and still more preferably 0.1 mol % or lower with respect to 1 mol of all the metal ions of the metal azo pigment.

The details of the metal azo pigment can be found in paragraphs “0011” to “0062” and “0137” to “0276” of JP2017-171912A, paragraphs “0010” to “0062” and “0138” to “0295” of JP2017-171913A, paragraphs “0011” to “0062” and “0139” to “0190” of JP2017-171914A, and paragraphs “0010” to “0065” and “0142” to “0222” of JP2017-171915A, the contents of which are incorporated herein by reference.

In addition, as the red pigment, a compound having a structure in which an aromatic ring group into which a group having an oxygen atom, a sulfur atom, or a nitrogen atom bonded to an aromatic ring is introduced is bonded to a diketo pyrrolo pyrrole skeleton can also be used. This compound is preferably a compound represented by Formula (DPP1) and more preferably a compound represented by Formula (DPP2).

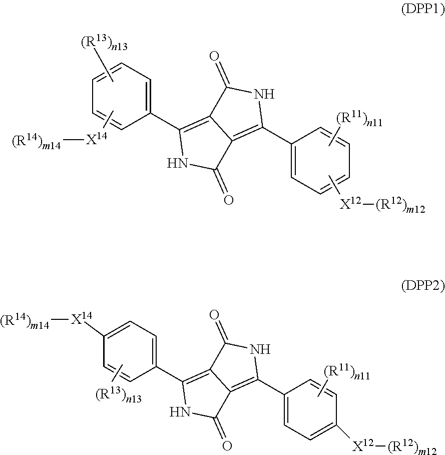

In the formula, R11 and R13 each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X¹² represents an oxygen atom or a sulfur atom, m12 represents 1, in a case where X¹² represents a nitrogen atom, m12 represents 2, in a case where X¹⁴ represents an oxygen atom or a sulfur atom, m14 represents 1, and in a case where X¹⁴ represents a nitrogen atom, m14 represents 2. Specific preferable example of the substituent represented by R¹¹ and R¹³ include an alkyl group, an aryl group, a halogen atom, an acyl group, an alkoxycarbonyl group, an aryloxycarbonyl group, a heteroaryloxycarbonyl group, an amido group, a cyano group, a nitro group, a trifluoromethyl group, a sulfoxide group, and a sulfo group.

In addition, as a green pigment, a halogenated zinc phthalocyanine pigment having 10 to 14 halogen atoms, 8 to 12 bromine atoms, and 2 to 5 chlorine atoms in one molecule on average can also be used. Specific examples of the green colorant include a compound described in WO2015/118720A.

In addition, as a blue pigment, an aluminum phthalocyanine compound having a phosphorus atom can also be used. Specific examples of the blue colorant include a compound described in paragraphs “0022” to “0030” of JP2012-247591A and paragraph “0047” of JP2011-157478A.

As the dye, well-known dyes can be used without any particular limitation. Examples of the dye include a dye such as a pyrazole azo dye, an anilino azo dye, a triarylmethane dye, an anthraquinone dye, an anthrapyridone dye, a benzylidene dye, an oxonol dye, a pyrazolotriazole azo dye, a pyridone azo dye, a cyanine dye, a phenothiazine dye, a pyrrolopyrazole azomethine dye, a xanthene dye, a phthalocyanine dye, a benzopyran dye, an indigo dye, and a pyrromethene dye. In addition, a polymer of the above-described dyes may be used. In addition, dyes described in JP2015-028144A and JP2015-034966A can also be used.

(Black Colorant)

Examples of the black colorant include an inorganic black colorant such as carbon black, a metal oxynitride (for example, titanium black), or a metal nitride (for example, titanium nitride) and an organic black colorant such as a bisbenzofuranone compound, an azomethine compound, a perylene compound, or an azo compound. As the organic black colorant, a bisbenzofuranone compound or a perylene compound is preferable. Examples of the bisbenzofuranone compound include a compound described in JP2010-534726A, JP2012-515233A, and JP2012-515234A. For example, “Irgaphor Black” (manufactured by BASF SE) is available. Examples of the perylene compound include C.I. Pigment Black 31 and 32. Examples of the azomethine compound include compounds described in JP1989-170601A (JP-H1-170601A) and JP1990-034664A (JP-H2-034664A). For example, “CHROMOFINE BLACK A1103” (manufactured by Dainichiseika Color & Chemicals Mfg. Co., Ltd.) is available. It is preferable that the bisbenzofuranone compound is one of compounds represented by the following formulae or a mixture thereof.

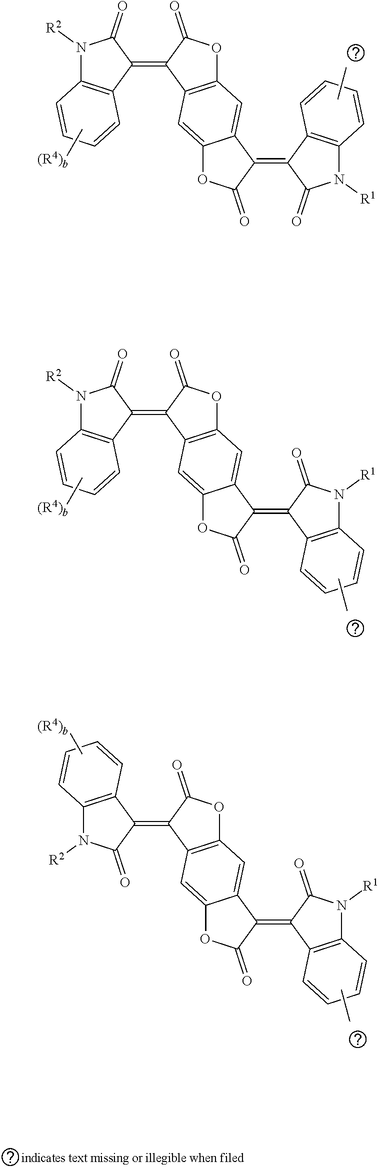

In the formulae, R¹ and R² each independently represent a hydrogen atom or a substituent, R³ and R⁴ each independently represent a substituent, a and b each independently represent an integer of 0 to 4, in a case where a is 2 or more, a plurality of R³'s may be the same as or different from each other, a plurality of R³'s may be bonded to each other to form a ring, in a case where b is 2 or more, a plurality of R⁴'s may be the same as or different from each other, and a plurality of R⁴'s may be bonded to each other to form a ring.

The substituent represented by R¹ to R⁴ is a halogen atom, a cyano group, a nitro group, an alkyl group, an alkenyl group, an alkynyl group, an aralkyl group, an aryl group, a heteroaryl group, —OR³⁰¹, —COR³⁰², —COOR³⁰³, —OCOR³⁰⁴, —NR³⁰⁵R³⁰⁶, —NHCOR³⁰⁷, —CONR³⁰⁸R³⁰⁹, —NHCONR³¹⁰R³¹¹, —NHCOOR³¹², —SR³¹³, —SO₂R³¹⁴, —SO₂OR³¹⁵, —NHSO₂R³¹⁶, or —SO₂NR³¹⁷R³¹⁸. R³⁰¹ to R³¹⁸ each independently represent a hydrogen atom, an alkyl group, an alkenyl group, an alkynyl group, an aryl group, or a heteroaryl group.

The details of the bisbenzofuranone compound can be found in paragraphs “0014” to “0037” of JP2010-534726A, the content of which is incorporated herein by reference.

(Infrared Absorbing Colorant)

As the infrared absorbing colorant, a compound having a maximum absorption wavelength preferably in a wavelength range of 700 to 1300 nm and more preferably in a wavelength range of 700 to 1000 nm is preferable. The infrared absorbing colorant may be a pigment or a dye.

In the present invention, as the infrared absorbing colorant, a compound that includes a π-conjugated plane having a monocyclic or fused aromatic ring can be preferably used. The number of atoms constituting the π-conjugated plane included in the infrared absorbing colorant other than hydrogen is preferably 14 or more, more preferably 20 or more, still more preferably 25 or more, and still more preferably 30 or more. For example, the upper limit is preferably 80 or less and more preferably 50 or less. The number of monocyclic or fused aromatic rings in the π-conjugated plane included in the infrared absorbing colorant is preferably 2 or more, more preferably 3 or more, still more preferably 4 or more, and still more preferably 5 or more. The upper limit is preferably 100 or less, more preferably 50 or less, and still more preferably 30 or less. Examples of the aromatic ring include a benzene ring, a naphthalene ring, a pentalene ring, an indene ring, an azulene ring, a heptalene ring, an indacene ring, a perylene ring, a pentacene ring, a quaterrylene ring, an acenaphthene ring, a phenanthrene ring, an anthracene ring, a naphthacene ring, a chrysene ring, a triphenylene ring, a fluorene ring, a pyridine ring, a quinoline ring, an isoquinoline ring, an imidazole ring, a benzimidazole ring, a pyrazole ring, a thiazole ring, a benzothiazole ring, a triazole ring, a benzotriazole ring, an oxazole ring, a benzoxazole ring, an imidazoline ring, a pyrazine ring, a quinoxaline ring, a pyrimidine ring, a quinazoline ring, a pyridazine ring, a triazine ring, a pyrrole ring, an indole ring, an isoindole ring, a carbazole ring, and a fused ring including the above-described ring.

As the infrared absorbing colorant, at least one selected from a pyrrolopyrrole compound, a cyanine compound, a squarylium compound, a phthalocyanine compound, a naphthalocyanine compound, a quaterrylene compound, a merocyanine compound, a croconium compound, an oxonol compound, a diimmonium compound, a dithiol compound, a triarylmethane compound, a pyrromethene compound, an azomethine compound, an anthraquinone compound, or a dibenzofuranone compound is preferable, at least one selected from a pyrrolopyrrole compound, a cyanine compound, a squarylium compound, a phthalocyanine compound, a naphthalocyanine compound, or a diimmonium compound is more preferable, at least one selected from a pyrrolopyrrole compound, a cyanine compound, a squarylium compound is still more preferable, and a pyrrolopyrrole compound is still more preferable.

Examples of the pyrrolopyrrole compound include compounds described in paragraphs “0016” to “0058” of JP2009-263614A, compounds described in paragraphs “0037” to “0052” of JP2011-068731A, compounds described in paragraphs “0010” to “0033” of WO2015/166873A, the contents of which are incorporated herein by reference.

Examples of the squarylium compound include a compound described in paragraphs “0044” to “0049” of JP2011-208101A, a compound described in paragraphs “0060” and “0061” of JP6065169B, a compound described in paragraph “0040” of WO2016/181987A, a compound described in WO2013/133099A, a compound described in WO2014/088063A, a compound described in JP2014-126642A, a compound described in JP2016-146619A, a compound described in JP2015-176046A, a compound described in JP2017-025311A, a compound described in WO2016/154782A, a compound described in JP5884953B, a compound described in JP6036689B, a compound described in JP5810604B, and a compound described in JP2017-068120A, the contents of which are incorporated herein by reference.

In addition, examples of the cyanine compound include a compound described in paragraphs “0044” and “0045” of JP2009-108267A, a compound described in paragraphs “0026” to “0030” of JP2002-194040, a compound described in JP2015-172004A, a compound described in JP2015-172102A, a compound described in JP2008-088426A, and a compound described in JP2017-031394A, the contents of which are incorporated herein by reference.

Examples of the diimmonium compound include a compound described in JP2008-528706A, the content of which is incorporated herein by reference. Examples of the phthalocyanine compound include a compound described in paragraph “0093” of JP2012-077153A, oxytitaniumphthalocyanine described in JP2006-343631A, and a compound described in paragraphs “0013” to “0029” of JP2013-195480A, the contents of which are incorporated herein by reference. Examples of the naphthalocyanine compound include a compound described in paragraph “0093” of JP2012-077153A, the content of which is incorporated herein by reference.

In the present invention, as the infrared absorbing colorant, a commercially available product can also be used. Examples of the commercially available product include SDO-C33 (manufactured by Arimoto Chemical Co., Ltd.); EXCOLOR IR-14, EXCOLOR IR-10A, EXCOLOR TX-EX-801B, and EXCOLOR TX-EX-805K (manufactured by Nippon Shokubai Co., Ltd.); Shigenox NIA-8041, Shigenox NIA-8042, Shigenox NIA-814, Shigenox NIA-820, and Shigenox NIA-839 (manufactured by Hakkol Chemical Co., Ltd.); Epolite V-63, Epolight 3801, and Epolight3036 (manufactured by Epolin Inc.); PRO-JET 825LDI (manufactured by Fujifilm Corporation); NK-3027 and NK-5060 (manufactured by Hayashibara Co., Ltd.); and YKR-3070 (manufactured by Mitsui Chemicals, Inc.).

From the viewpoint of reducing the thickness of the obtained film, the content of the coloring material is preferably 40 mass % or higher, more preferably 50 mass % or higher, still more preferably 55 mass % or higher, and still more preferably 60 mass % or higher with respect to the total solid content of the photosensitive composition. In a case where the content of the coloring material is 40 mass % or higher, a thin film having excellent spectral characteristics can be easily obtained. From the viewpoint of film forming properties, the upper limit is preferably 80 mass % or lower, more preferably 75 mass % or lower, and still more preferably 70 mass % or lower.

It is preferable that the coloring material used in the photosensitive composition according to the embodiment of the present invention includes at least one selected from a chromatic colorant or a black colorant. In addition, the content of the chromatic colorant and the black colorant is preferably 30 mass % or higher, more preferably 50 mass % or higher, and still more preferably 70 mass % or higher with respect to the total mass of the coloring material. The upper limit may be 100 mass % or may be 90 mass % or lower.

In addition, it is preferable that the coloring material used in the photosensitive composition according to the embodiment of the present invention includes at least a green colorant. In addition, the content of the green colorant is preferably 30 mass % or higher, more preferably 40 mass % or higher, and still more preferably 50 mass % or higher with respect to the total mass of the coloring material. The upper limit may be 100 mass % or may be 75 mass % or lower.

In the coloring material used in the photosensitive composition according to the embodiment of the present invention, the content of the pigment is preferably 50 mass % or higher, more preferably 70 mass % or higher, and still more preferably 90 mass % or higher with respect to the total mass of the coloring material. In a case where the content of the pigment is in the above-described range with respect to the total mass of the coloring material, a film in which a spectral variation caused by heat is suppressed can be easily obtained.

In a case where the photosensitive composition according to the embodiment of the present invention is used as a composition for color filter (more specifically, a composition for forming a colored pixel of a color filter), the content of the chromatic colorant is preferably 40 mass % or higher, more preferably 50 mass % or higher, still more preferably 55 mass % or higher, and still more preferably 60 mass % or higher with respect to the total solid content of the photosensitive composition. In addition, the content of the chromatic colorant is preferably 25 mass % or higher, more preferably 45 mass % or higher, and still more preferably 65 mass % or higher with respect to the total mass of the coloring material. The upper limit may be 100 mass % or may be 75 mass % or lower. In addition, it is preferable that the coloring material includes at least a green colorant. In addition, the content of the green colorant is preferably 35 mass % or higher, more preferably 45 mass % or higher, and still more preferably 55 mass % or higher with respect to the total mass of the coloring material. The upper limit may be 100 mass % or may be 80 mass % or lower.

In a case where the photosensitive composition according to the embodiment of the present invention is used as a composition for forming a light blocking film, the content of the black colorant (preferably the inorganic black colorant) is preferably 40 mass % or higher, more preferably 50 mass % or higher, still more preferably 55 mass % or higher, and still more preferably 60 mass % or higher with respect to the total solid content of the photosensitive composition. In addition, the content of the black colorant is preferably 30 mass % or higher, more preferably 50 mass % or higher, and still more preferably 70 mass % or higher with respect to the total mass of the coloring material. The upper limit may be 100 mass % or may be 90 mass % or lower.

In a case where the photosensitive composition according to the embodiment of the present invention is used as a composition for an infrared transmitting filter, it is preferable that the coloring material used in the present invention satisfies at least one of the following requirements (1) to (3).

(1): The coloring material that blocks visible light includes two or more chromatic colorants, and a combination of the two or more chromatic colorants forms black. That is, it is preferable that the coloring material forms black using a combination of two or more colorants selected from a red colorant, a blue colorant, a yellow colorant, a violet colorant, and a green colorant.

(2): The coloring material includes an organic black colorant.

(3): In (1) or (2), the coloring material further includes an infrared absorbing colorant.

Examples of a preferable combination in the aspect (1) are as follows.

(1-1) An aspect in which the coloring material includes a red colorant and a blue colorant.

(1-2) An aspect in which the coloring material includes a red colorant, a blue colorant, and a yellow colorant.

(1-3) An aspect in which the coloring material includes a red colorant, a blue colorant, a yellow colorant, and a violet colorant.

(1-4) An aspect in which the coloring material includes a red colorant, a blue colorant, a yellow colorant, a violet colorant, and a green colorant.

(1-5) An aspect in which the coloring material includes a red colorant, a blue colorant, a yellow colorant, and a green colorant.

(1-6) An aspect in which the coloring material includes a red colorant, a blue colorant, and a green colorant.

(1-7) An aspect in which the coloring material includes a yellow colorant and a violet colorant.

In the aspect (2), it is preferable that the coloring material further includes a chromatic colorant. By using the organic black colorant in combination with a chromatic colorant, excellent spectral characteristics are likely to be obtained. Examples of the chromatic colorant which can be used in combination with the organic black colorant include a red colorant, a blue colorant, and a violet colorant. Among these, a red colorant or a blue colorant is preferable. Among these colorants, one kind may be used alone, or two or more kinds may be used in combination. In addition, regarding a mixing ratio between the chromatic colorant and the organic black colorant, the amount of the chromatic colorant is preferably 10 to 200 parts by mass and more preferably 15 to 150 parts by mass with respect to 100 parts by mass of the organic black colorant.

In the aspect (3), the content of the infrared absorbing colorant is preferably 5 to 40 mass % with respect to the total mass of the coloring material. The upper limit is preferably 30 mass % or lower and more preferably 25 mass % or lower. The lower limit is preferably 10 mass % or higher and more preferably 15 mass % or higher.

<<Resin>>

The photosensitive composition according to the embodiment of the present invention may include a resin. The resin according to the embodiment of the present invention refers to an organic compound having a molecular weight of 2000 or higher other than a coloring material. The resin is added, for example, in order to disperse particles of the pigments and the like in the composition or to be added as a binder. The resin which is mainly used to disperse particles of the pigments and the like will also be called a dispersant. However, the above-described uses of the resin are merely exemplary, and the resin can be used for purposes other than the uses. The resin having a radically polymerizable group is a component that also corresponds to the radically polymerizable compound.

The weight-average molecular weight (Mw) of the resin is preferably 2000 to 2000000. The upper limit is preferably 1000000 or lower and more preferably 500000 or lower. The lower limit is preferably 3000 or higher and more preferably 5000 or higher.

Examples of the resin include a (meth)acrylic resin, an enethiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide imide resin, a polyolefin resin, a cyclic olefin resin, a polyester resin, and a styrene resin. Among these resins, one kind may be used alone, or a mixture of two or more kinds may be used. As the cyclic olefin resin, a norbomene resin can be preferably used from the viewpoint of improving heat resistance. Examples of a commercially available product of the norbomene resin include ARTON series (for example, ARTON F4520, manufactured by JSR Corporation). In addition, as the resin, a resin described in Examples of WO2016/088645A, a resin described in JP2017-057265A, a resin described in JP2017-032685A, a resin described in JP2017-075248A, or a resin described in JP2017-066240A can also be used, the contents of which are incorporated herein by reference.

In the present invention, it is preferable that a resin having an acid group is used as the resin. In this aspect, the developability of the photosensitive composition can be improved, and a pixel having excellent rectangularity can be easily formed. Examples of the acid group include a carboxyl group, a phosphate group, a sulfo group, and a phenolic hydroxy group. Among these, a carboxyl group is preferable. The resin having an acid group can be used as, for example, an alkali-soluble resin.

It is preferable that the resin having an acid group further includes a repeating unit having an acid group at a side chain, and it is more preferable that the content of the repeating unit having an acid group at a side chain is preferably 5 to 70 mol % with respect to all the repeating units of the resin. The upper limit of the content of the repeating unit having an acid group at a side chain is preferably 50 mol % or lower and more preferably 30 mol % or lower. The lower limit of the content of the repeating unit having an acid group at a side chain is preferably 10 mol % or higher and more preferably 20 mol % or higher.

It is also preferable that the resin having an acid group includes a repeating unit derived from monomer components including a compound represented by the following Formula (ED1) and/or a compound represented by the following Formula (ED2) (hereinafter, these compounds will also be referred to as “ether dimer”).

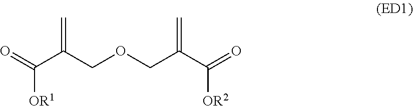

In Formula (ED1), R¹ and R² each independently represent a hydrogen atom or a hydrocarbon group having 1 to 25 carbon atoms which may have a substituent.

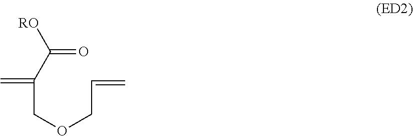

In Formula (ED2), R represents a hydrogen atom or an organic group having 1 to 30 carbon atoms. The details of Formula (ED2) can be found in JP2010-168539A, the content of which is incorporated herein by reference.

Specific examples of the ether dimer can be found in paragraph “0317” of JP2013-029760A, the content of which is incorporated herein by reference.

It is also preferable that the resin used in the present invention includes a repeating unit which is derived from a compound represented by the following Formula (X).

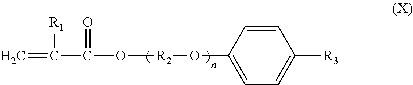

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring. n represents an integer of 1 to 15.

Examples of the resin having an acid group include resins having the following structures. Among resins shown in the following specific examples, the resin having a radically polymerizable group is a component that also corresponds to the radically polymerizable compound.

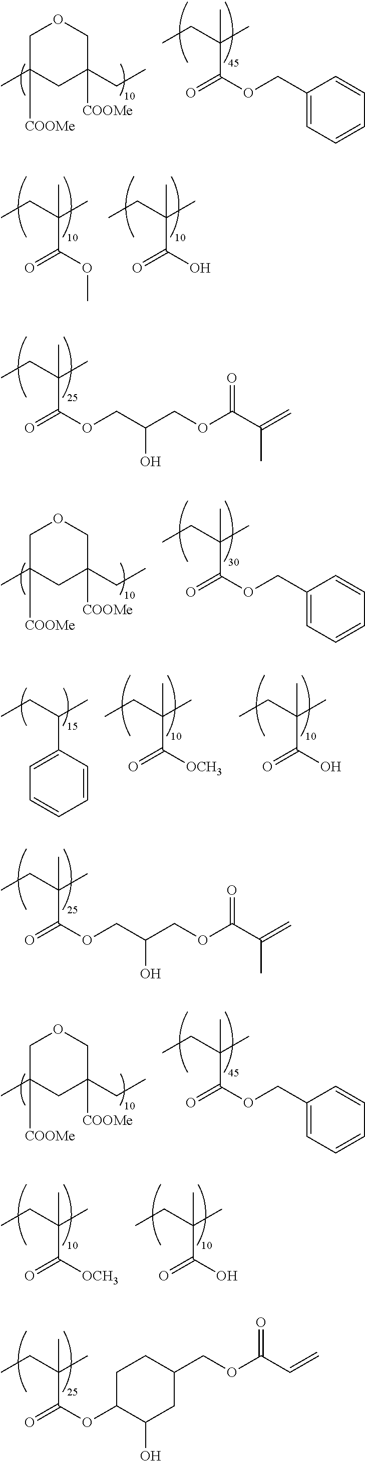

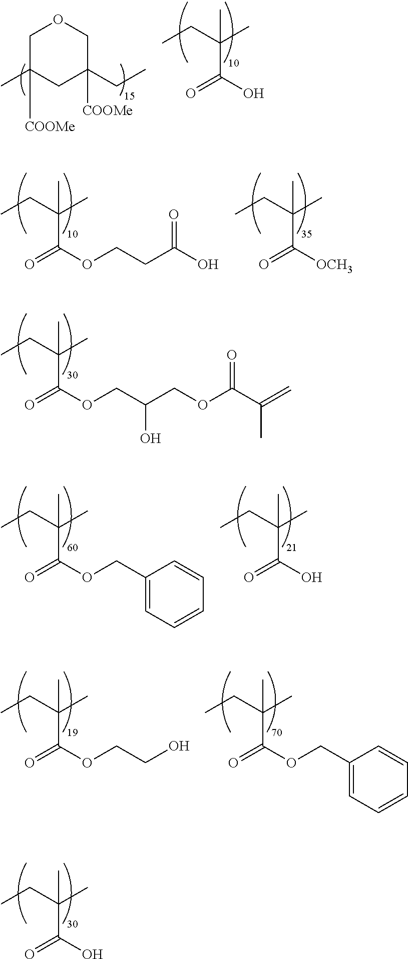

The details of the resin having an acid group can be found in paragraphs “0558” to “0571” of JP2012-208494A (corresponding to paragraphs “0685” to “0700” of US2012/0235099A), the content of which is incorporated herein by reference. In addition, a copolymer (B) described in paragraphs “0029” to “0063” and an alkali-soluble resin used in Examples of JP2012-32767A, a binder resin described in paragraphs “0088” to “0098” and a binder resin used in Examples of JP2012-208474A, a binder resin described in paragraphs “0022” to “0032 and a binder resin used in Examples of JP2012-137531A, a binder resin described in paragraphs “0132” to “0143” and a binder resin used in Examples of JP2013-024934A, a binder resin described in paragraphs “0092” to “0098” and Examples of JP2011-242752A, or a binder resin described in paragraphs “0030” to “0072” of JP2012-032770A can also be used. In this specification, the contents are incorporated herein by reference.

The acid value of the resin having an acid group is preferably 30 to 500 mgKOH/g. The lower limit is more preferably 50 mgKOH/g or higher, still more preferably 70 mgKOH/g or higher, and still more preferably 80 mgKOH/g or higher. The upper limit is more preferably 400 mgKOH/g or lower and still more preferably 250 mgKOH/g or lower.

The weight-average molecular weight (Mw) of the resin having an acid group is preferably 5000 to 100000. In addition, the number-average molecular weight (Mn) of the resin having an acid group is preferably 1000 to 20000.

The photosensitive composition according to the embodiment of the present invention may include a resin as a dispersant. Examples of the dispersant include an acidic dispersant (acidic resin) and a basic dispersant (basic resin). Here, the acidic dispersant (acidic resin) refers to a resin in which the content of an acid group is more than the content of a basic group. In a case where the sum of the amount of an acid group and the amount of a basic group in the acidic dispersant (acidic resin) is represented by 100 mol %, the amount of the acid group in the acidic resin is preferably 70 mol % or higher and more preferably substantially 100 mol %. The acid group in the acidic dispersant (acidic resin) is preferably a carboxyl group. An acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) refers to a resin in which the amount of a basic group is more than the amount of an acid group. In a case where the sum of the amount of an acid group and the amount of a basic group in the basic dispersant (basic resin) is represented by 100 mol %, the amount of the basic group in the basic resin is preferably higher than 50 mol %. The basic group in the basic dispersant is preferably an amino group.

It is preferable that the resin used as the dispersant further includes a repeating unit having an acid group. By the resin, which is used as the dispersant, including the repeating unit having an acid group, in a case where a pixel is formed using a photolithography method, the amount of residues formed in an underlayer of a pixel can be reduced, and a photosensitive composition having excellent developability can be obtained.

It is preferable that the resin used as the dispersant is a graft copolymer. Since the graft copolymer has affinity to the solvent due to the graft chain, the pigment dispersibility and the dispersion stability over time are excellent. The details of the graft copolymer can be found in the description of paragraphs “0025” to “0094” of JP2012-255128A, the content of which is incorporated herein by reference. In addition, specific examples of the graft copolymer include the following resins. The following resin may also be a resin having an acid group (alkali-soluble resin). In addition, other examples of the graft copolymer include resins described in paragraphs “0072” to “0094” of JP2012-255128A, the content of which is incorporated herein by reference.

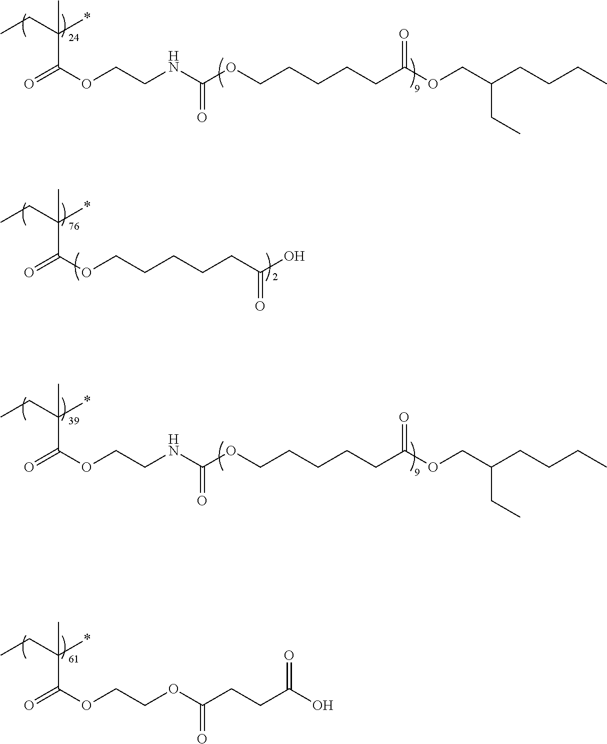

In addition, in the present invention, as the resin (dispersant), an oligoimine copolymer having a nitrogen atom at at least either a main chain or a side chain is also preferably used. As the oligoimine copolymer, a resin, which includes a structural unit having a partial structure X with a functional group (pKa: 14 or lower) and a side chain including a side chain Y having 40 to 10,000 atoms and has a basic nitrogen atom at at least either a main chain or a side chain, is preferable. The basic nitrogen atom is not particularly limited as long as it is a nitrogen atom exhibiting basicity. The oligoimine copolymer can be found in the description of paragraphs “0102” to “0166” of JP2012-255128A, the content of which is incorporated herein by reference. As the oligoimine copolymer, a resin having the following structure or a resin described in paragraphs “0168” to “0174” of JP2012-255128A can be used.

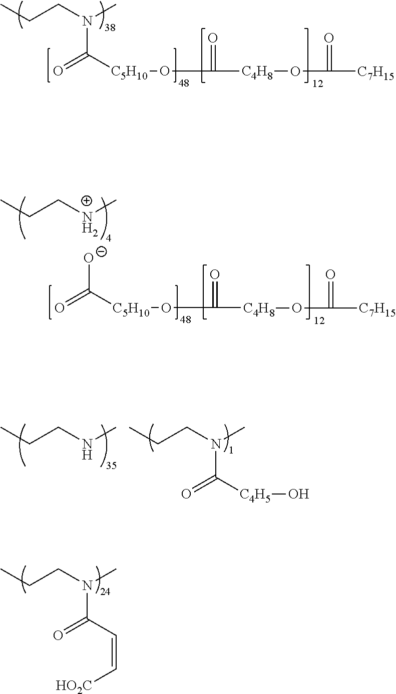

In addition, the alkali-soluble resin can also be used as a dispersant.

In addition, it is also preferable that the resin used as a dispersant is a resin that includes a repeating unit having an ethylenically unsaturated bond group at a side chain. The content of the repeating unit having an ethylenically unsaturated bond group at a side chain is preferably 10 mol % or higher, more preferably 10% to 80 mol %, and still more preferably 20% to 70 mol % with respect to all the repeating units of the resin.

As the dispersant, a commercially available product can also be used. For example, a product described in paragraph “0129” of JP2012-137564A can also be used as a dispersant. Examples of the product include DISKERBYK series (manufactured by BYK Chemie, for example, DISKERBYK-161). The resin described as the dispersant can also be used for a use other than a dispersant. For example, the resin can also be used as a binder.

In a case where the photosensitive composition according to the embodiment of the present invention includes the resin, the content of the resin (in a case where the radically polymerizable compound includes a radically polymerizable polymer, the content of the radically polymerizable polymer) is preferably 5% to 50 mass % with respect to the total solid content of the photosensitive composition. The lower limit is preferably 10 mass % or higher and more preferably 15 mass % or higher. The upper limit is preferably 40 mass % or lower, more preferably 35 mass % or lower, and still more preferably 30 mass % or lower.

In addition, the content of the resin having an acid group (in a case where the radically polymerizable compound includes a radically polymerizable polymer having an acid group, the content of the radically polymerizable polymer having an acid group) is preferably 5% to 50 mass % with respect to the total solid content of the photosensitive composition. The lower limit is preferably 10 mass % or higher and more preferably 15 mass % or higher. The upper limit is preferably 40 mass % or lower, more preferably 35 mass % or lower, and still more preferably 30 mass % or lower.

In addition, from the viewpoint of easily obtaining excellent developability, the content of the resin having an acid group is preferably 30 mass % or higher, more preferably 50 mass % or higher, still more preferably 70 mass % or higher, and still more preferably 80 mass % or higher with respect to the total content of the resin. The upper limit may be 100 mass % or lower, 95 mass % or lower, or 90 mass % or lower.

In addition, the total content of the radically polymerizable monomer and the resin is preferably 15% to 65 mass % with respect to the total solid content of the photosensitive composition from the viewpoint of simultaneously improving curing properties, developability, and coating properties. The lower limit is preferably 20 mass % or higher, more preferably 25 mass % or higher, and still more preferably 30 mass % or higher. The upper limit is preferably 60 mass % or lower, more preferably 55 mass % or lower, and still more preferably 50 mass % or lower. In addition, the content of the resin is preferably 30 to 300 parts by mass with respect to 100 parts by mass of the radically polymerizable monomer. The lower limit is preferably 50 parts by mass or more and more preferably 80 parts by mass or more. The upper limit is preferably 250 parts by mass or less and more preferably 200 parts by mass or less.

<<Compound having Cyclic Ether Group>>

The photosensitive composition according to the embodiment of the present invention may include a compound having a cyclic ether group. Examples of the cyclic ether group include an epoxy group and an oxetanyl group. It is also preferable that the compound having a cyclic ether group is a compound having an epoxy group. Examples of the compound having an epoxy group include a compound having one or more epoxy groups in one molecule. In particular, a compound having two or more epoxy groups in one molecule is preferable. The number of epoxy groups in one molecule is preferably 1 to 100. The upper limit of the number of epoxy groups is, for example, 10 or less or 5 or less. The lower limit of the number of epoxy groups is preferably 2 or more. As the compound having an epoxy group, a compound described in paragraphs “0034” to “0036” of JP2013-011869A, paragraphs “0147” to “0156” of JP2014-043556A, or paragraphs “0085” to “0092” of JP2014-089408A or a compound described in JP2017-179172A can also be used. In this specification, the contents are incorporated herein by reference.

The compound having an epoxy group may be a low molecular weight compound (for example, molecular weight: lower than 2000 or lower than 1000) or a high molecular weight compound (macromolecule; for example, molecular weight: 1000 or higher, and in the case of a polymer, weight-average molecular weight: 1000 or higher). The weight-average molecular weight of the compound having an epoxy group is preferably 200 to 100000 and more preferably 500 to 50000. The upper limit of the weight-average molecular weight is preferably 10000 or lower, more preferably 5000 or lower, and still more preferably 3000 or lower.

As the compound having an epoxy group, an epoxy resin can be preferably used. Examples of the epoxy resin include an epoxy resin which is a glycidyl-etherified product of a phenol compound, an epoxy resin which is a glycidyl-etherified product of various novolac resins, an alicyclic epoxy resin, an aliphatic epoxy resin, a heterocyclic epoxy resin, a glycidyl ester epoxy resin, a glycidyl amine epoxy resin, an epoxy resin which is a glycidylated product of a halogenated phenol, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, or G-01758 (manufactured by NOF Corporation, an epoxy group-containing polymer).

In a case where the photosensitive composition according to the embodiment of the present invention includes the compound having a cyclic ether group, the content of the compound having a cyclic ether group is preferably 0.1% to 20 mass % with respect to the total solid content of the photosensitive composition. For example, the lower limit is more preferably 0.5 mass % or higher and still more preferably 1 mass % or higher. For example, the upper limit is preferably 15 mass % or lower and more preferably 10 mass % or lower. As the compound having a cyclic ether group, one kind may be used alone, or two or more kinds may be used. In a case where the photosensitive composition includes two or more pigment derivatives, it is preferable that the total content of the two or more pigment derivatives is in the above-described range.

<<Silane Coupling Agent>>

The photosensitive composition according to the embodiment of the present invention may include a silane coupling agent. In this aspect, the adhesiveness of the obtained film with the support can be improved. In the present invention, the silane coupling agent refers to a silane compound having a functional group other than a hydrolyzable group. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group. Among these, an alkoxy group is preferable. That is, it is preferable that the silane coupling agent is a compound having an alkoxysilyl group. Examples of the functional group other than a hydrolyzable group include a vinyl group, a (meth)allyl group, a (meth)acryloyl group, a mercapto group, an epoxy group, an oxetanyl group, an amino group, an ureido group, a sulfide group, an isocyanate group, and a phenyl group. Among these, an amino group, a (meth)acryloyl group, or an epoxy group is preferable. Specific examples of the silane coupling agent include a compound described in paragraphs “0018” to “0036” of JP2009-288703A and a compound described in paragraphs “0056” to “0066” of JP2009-242604A, the contents of which are incorporated herein by reference.

The content of the silane coupling agent is preferably 0.1% to 5 mass % with respect to the total solid content of the photosensitive composition. The upper limit is preferably 3 mass % or lower, and more preferably 2 mass % or lower. The lower limit is preferably 0.5 mass % or higher and more preferably 1 mass % or higher. As the silane coupling agent, one kind may be used alone, or two or more kinds may be used. In a case where two or more surfactants are used in combination, it is preferable that the total content of the two or more surfactants is in the above-described range.

<<Pigment Derivative>>

The photosensitive composition according to the embodiment of the present invention may further include a pigment derivative. Examples of the pigment derivative include a compound having a structure in which a portion of a pigment is substituted with an acid group, a basic group, a group having a salt structure, or a phthalimidomethyl group. As the pigment derivative, a compound represented by Formula (B1) is preferable.

PL-(X)ₙ)ₘ (B1)

In Formula (B1), P represents a colorant structure, L represents a single bond or a linking group, X represents an acid group, a basic group, a group having a salt structure, or a phthalimidomethyl group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

The colorant structure represented by P is preferably at least one selected from a pyrrolopyrrole colorant structure, a diketo pyrrolopyrrole colorant structure, a quinacridone colorant structure, an anthraquinone colorant structure, a dianthraquinone colorant structure, a benzoisoindole colorant structure, a thiazine indigo colorant structure, an azo colorant structure, a quinophthalone colorant structure, a phthalocyanine colorant structure, a naphthalocyanine colorant structure, a dioxazine colorant structure, a perylene colorant structure, a perinone colorant structure, a benzimidazolone colorant structure, a benzothiazole colorant structure, a benzimidazole colorant structure, and a benzoxazole colorant structure, and more preferably at least one selected from a pyrrolopyrrole colorant structure, a diketo pyrrolo pyrrolopyrrole colorant structure, a quinacridone colorant structure, or a benzimidazolone colorant structure.

Examples of the linking group represented by L include a hydrocarbon group, a heterocyclic group, —NR—, —SO₂—, —S—, —O—, —CO—, and a group consisting of a combination thereof. R represents a hydrogen atom, an alkyl group, or an aryl group.

Examples of the acid group represented by X include a carboxyl group, a sulfo group, a carboxylic acid amide group, a sulfonic acid amide group, and an imide acid group. As the carboxylic acid amide group, a group represented by —NHCOR^{X1} is preferable. As the sulfonic acid amide group, a group represented by —NHSO₂R^{X2} is preferable. As the imide acid group, a group represented by —SO₂NHSO₂R^{X3}, —CONHSO₂R^{X4}, —CONHCOR^{X5}, or —SO₂NHCOR^{X6} is preferable. R^{X1} to R^{X6} each independently represent a hydrocarbon group or a heterocyclic group. The hydrocarbon group and the heterocyclic group represented by R^{X1} to R^{X6} may further have a substituent. As the substituent which may be further included, a halogen atom is preferable, and a fluorine atom is more preferable. Examples of the basic group represented by X include an amino group. Examples of the salt structure represented by X include a salt of the acid group or the basic group described above.

Examples of the pigment derivative include compounds having the following structures. In addition, for example, compounds described in JP1981-118462A (JP-S56-118462A), JP1988-264674A (JP-S63-264674A), JP1989-217077A (JP-H1-217077A), JP1991-009961A (JP-H3-009961A), JP1991-026767A (JP-H3-026767A), JP1991-153780A (JP-H3-153780A), JP1991-045662A (JP-H3-045662A), JP1992-285669A (JP-H4-285669A), JP1994-145546A (JP-H6-145546A), JP1994-212088A (JP-H6-212088A), JP1994-240158A (JP-H6-240158A), JP1998-030063A (JP-H10-030063A), JP1998-195326A (JP-H10-195326A), paragraphs “0086” to “0098” of WO2011/024896A, paragraphs “0063” to “0094” of WO2012/102399A, and paragraph “0082” of WO2017/038252A can be used, the content of which is incorporated herein by reference.

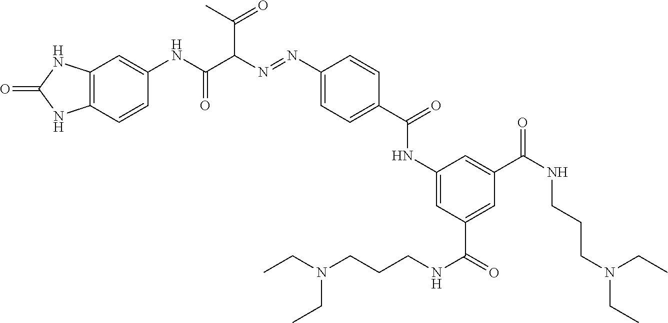 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

The content of the pigment derivative is preferably 1 to 50 parts by mass with respect to 100 parts by mass of the pigment. The lower limit value is preferably 3 parts by mass or more and more preferably 5 parts by mass or more. The upper limit value is preferably 40 parts by mass or less and more preferably 30 parts by mass or less. In a case where the content of the pigment derivative is in the above-described range, the pigment dispersibility can be improved, and aggregation of the pigment can be efficiently suppressed. As the pigment derivative, one kind may be used alone, or two or more kinds may be used in combination. In a case where two or more ultraviolet absorbers are used in combination, it is preferable that the total content of the two or more ultraviolet absorbers is in the above-described range.

<<Solvent>>

The photosensitive composition according to the embodiment of the present invention may include a solvent. Examples of the solvent include an organic solvent. Basically, the solvent is not particularly limited as long as it satisfies the solubility of the respective components and the application properties of the composition. Examples of the organic solvent include esters, ethers, ketones, and aromatic hydrocarbons. The details of the organic solvent can be found in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, and propylene glycol monomethyl ether acetate. In the present invention, as the organic solvent, one kind may be used alone, or two or more kinds may be used in combination. In addition, 3-methoxy-N,N-dimethylpropanamide or 3-butoxy-N,N-dimethylpropanamide is also preferable from the viewpoint of improving solubility. In this case, it may be preferable that the content of the aromatic hydrocarbon (for example, benzene, toluene, xylene, or ethylbenzene) as the solvent is low (for example, 50 mass parts per million (ppm) or lower, 10 mass ppm or lower, or 1 mass ppm or lower with respect to the total mass of the organic solvent) in consideration of environmental aspects and the like.

In the present invention, a solvent having a low metal content is preferably used. For example, the metal content in the solvent is preferably 10 mass parts per billion (ppb) or lower. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method of removing impurities such as metal from the solvent include distillation (for example, molecular distillation or thin-film distillation) and filtering using a filter. The pore size of a filter used for the filtering is preferably 10 μm or less, more preferably 5 μm or less, and still more preferably 3 μm or less. As a material of the filter, polytetrafluoroethylene, polyethylene, or nylon is preferable.

The solvent may include an isomer (a compound having the same number of atoms and a different structure). In addition, the organic solvent may include only one isomer or a plurality of isomers.

In the present invention, as the organic solvent, an organic solvent containing 0.8 mmol/L or lower of a peroxide is preferable, and an organic solvent containing substantially no peroxide is more preferable.

The content of the solvent in the photosensitive composition is preferably 10% to 95 mass %, more preferably 20% to 90 mass %, and still more preferably 30% to 90 mass %.

In addition, it is preferable that the photosensitive composition according to the embodiment of the present invention does not substantially include an environmentally regulated material from the viewpoint of environmental regulations. In the present invention, not substantially including the environmentally regulated material represents that the content of the environmentally regulated material in the photosensitive composition is 50 mass ppm or lower, preferably 30 mass ppm or lower, more preferably 10 mass ppm or lower, and still more preferably 1 mass ppm or lower. Examples of the environmentally regulated material include: benzene; an alkylbenzene such as toluene or xylene; and a halogenated benzene such as chlorobenzene. These compounds are registered as environmentally regulated materials based on Registration Evaluation Authorization and Restriction of Chemicals (REACH) regulation, Pollutant Release and Transfer Register (PRTR) method, Volatile Organic Compounds (VOC) regulation, and the like, and the amount thereof used and a handling method thereof are strictly regulated. These compounds are used as solvents in a case where each of the components or the like used in the photosensitive composition according to the embodiment of the present invention is manufactured, and may be incorporated into the photosensitive composition as residual solvents. From the viewpoints of safety for humans and consideration of the environment, it is preferable that these materials are reduced as much as possible. Examples of a method of reducing the environmentally regulated material include a method of distilling off the environmentally regulated material from the system by heating or depressurizing the system such that the temperature of the system is higher than or equal to a boiling point of the environmentally regulated material. In addition, in a case where a small amount of environmentally regulated material is removed by distillation, a method of azeotroping the environmentally regulated material with a solvent having the same boiling point as that of the corresponding solvent is also useful to increase the efficiency. In addition, in a case where a radically polymerizable compound is included, in order to suppress intermolecular crosslinking caused by the progress of a radical polymerization reaction during distillation under reduced pressure, a polymerization inhibitor or the like may be added for distillation under reduced pressure. This distillation method can be performed in, for example, any of a step of raw materials, a step of a reaction product (for example, a resin solution or a polyfunctional monomer solution after polymerization) obtained from a reaction of the raw materials, or a step of a composition prepared by mixing these compounds with each other.

<<Polymerization Inhibitor>>

The photosensitive composition according to the embodiment of the present invention may include a polymerization inhibitor. Examples of the polymerization inhibitor include hydroquinone, p-methoxyphenol, di-tert-butyl-p-cresol, pyrogallol, benzoquinone, and an N-nitrosophenylhydroxyamine salt (for example, an ammonium salt or a cerium (III) salt). Among these, p-methoxyphenol is preferable. The content of the polymerization inhibitor is preferably 0.001% to 5 mass % with respect to the total solid content of the photosensitive composition.

<<Surfactant>>

The photosensitive composition according to the embodiment of the present invention may include a surfactant. As the surfactants, various surfactants such as a fluorine surfactant, a nonionic surfactant, a cationic surfactant, an anionic surfactant, or a silicone surfactant can be used. The details of the surfactant can be found in paragraphs “0238” to “0245” of WO2015/166779A, the content of which is incorporated herein by reference.

In the present invention, it is preferable that the surfactant is a fluorine surfactant. By the photosensitive composition containing a fluorine surfactant, liquid characteristics (in particular, fluidity) are further improved, and liquid saving properties can be further improved. In addition, a film having reduced thickness unevenness can be formed.

The fluorine content in the fluorine surfactant is preferably 3 to 40 mass %, more preferably 5 to 30 mass %, and still more preferably 7 to 25 mass %. The fluorine surfactant in which the fluorine content is in the above-described range is effective from the viewpoints of the uniformity in the thickness of the coating film and liquid saving properties, and the solubility thereof in the composition is also excellent.

Examples of the fluorine surfactant include a surfactant described in paragraphs “0060” to “0064” of JP2014-041318A (paragraphs “0060” to “0064” of corresponding WO2014/017669A) and a surfactant described in paragraphs “0117” to “0132” of JP2011-132503A, the contents of which are incorporated herein by reference. Examples of a commercially available product of the fluorine surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine surfactant, an acrylic compound having a molecular structure which has a functional group having a fluorine atom and in which the functional group having a fluorine atom is cut and a fluorine atom is volatilized during heat application can also be preferably used. Examples of the fluorine surfactant include MEGAFACE DS series (manufactured by DIC Corporation, The Chemical Daily, Feb. 22, 2016, Nikkei Business Daily, Feb. 23, 2016), for example, MEGAFACE DS-21.

In addition, as the fluorine surfactant, a polymer of a fluorine-containing vinyl ether compound having a fluorinated alkyl group or a fluorinated alkylene ether group and a hydrophilic vinyl ether compound is also preferable. The details of this fluorine surfactant can be found in JP2016-216602A, the content of which is incorporated herein by reference.

As the fluorine surfactant, a block polymer can also be used. Examples of the block polymer include a compound described in JP2011-089090A. As the fluorine surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group). For example, the following compound can also be used as the fluorine surfactant used in the present invention.

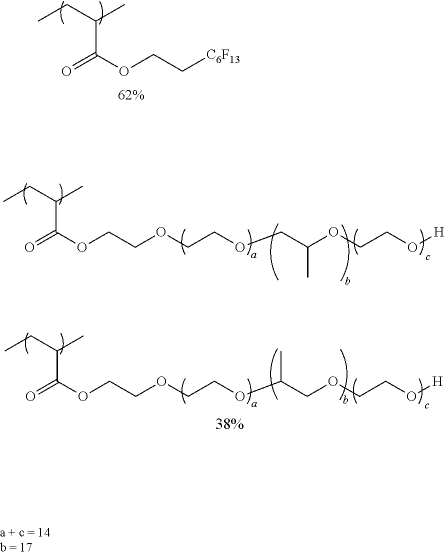

The weight-average molecular weight of the compound is preferably 3,000 to 50,000 and, for example, 14,000. In the compound, “%” representing the proportion of a repeating unit is mol %.

In addition, as the fluorine surfactant, a fluorine-containing polymer having an ethylenically unsaturated bond group at a side chain can also be used. Specific examples include a compound described in paragraphs “0050” to “0090” and paragraphs “0289” to “0295” of JP2010-164965A, for example, MEGAFACE RS-101, RS-102, RS-718K, and RS-72-K manufactured by DIC Corporation. As the fluorine surfactant, a compound described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE)), SOLSPERSE 20000 (manufactured by Lubrication Technology Inc.), NCW-101, NCW-1001, and NCW-1002 (all of which are manufactured by Fujifilm Wako Pure Chemical Corporation), PIONIN D-6112, D-6112-W, and D-6315 (all of which are manufactured by Takemoto Oil&Fat Co., Ltd.), and OLFINE E1010, SURFYNOL 104, 400, and 440 (all of which are manufactured by Nissin Chemical Co., Ltd.).

Examples of the silicone surfactant include: TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Corporation); TSF-4440, TSF-4300, TSF-4445, TSF-4460, and TSF-4452 (all of which are manufactured by Momentive Performance Materials Inc.); KP-341, KF-6001, and KF-6002 (all of which are manufactured by Shin-Etsu Chemical Co., Ltd.); and BYK307, BYK323, and BYK330 (all of which are manufactured by BYK-Chemie Japan K.K.). In addition, as the silicone surfactant, a compound having the following structure can also be used.

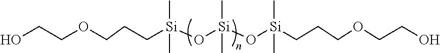

The content of the surfactant is preferably 0.001 mass % to 5.0 mass % and more preferably 0.005% to 3.0 mass % with respect to the total solid content of the photosensitive composition. As the surfactant, one kind may be used alone, or two or more kinds may be used. In a case where two or more surfactants are used in combination, it is preferable that the total content of the two or more surfactants is in the above-described range.

<<Ultraviolet Absorber>>

The photosensitive composition according to the embodiment of the present invention may include an ultraviolet absorber. As the ultraviolet absorber, a conjugated diene compound, an amino diene compound, a salicylate compound, a benzophenone compound, a benzotriazole compound, an acrylonitrile compound, a hydroxyphenyltriazine compound an indole compound, or a triazine compound can be used. The details of the ultraviolet absorber can be found in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Specific examples of the ultraviolet absorber include compounds having the following structures. Examples of a commercially available product of the ultraviolet absorber include UV-503 (manufactured by Daito Chemical Co., Ltd.). In addition, examples of the benzotriazole compound include MYUA series (manufactured by Miyoshi Oil&Fat Co., Ltd.; The Chemical Daily, Feb. 1, 2016).

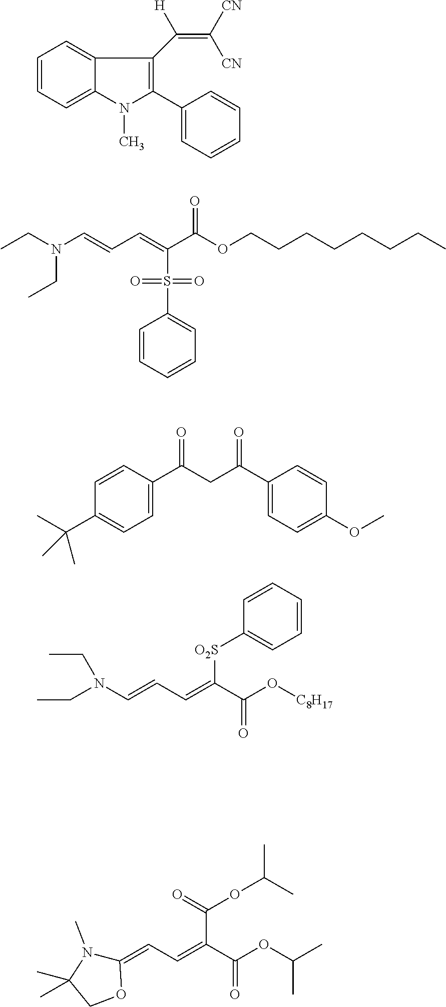

The content of the ultraviolet absorber is preferably 0.01% to 10 mass % and more preferably 0.01% to 5 mass % with respect to the total solid content of the photosensitive composition. In the present invention, as the ultraviolet absorber, one kind may be used alone, or two or more kinds may be used. In a case where two or more ultraviolet absorbers are used in combination, it is preferable that the total content of the two or more ultraviolet absorbers is in the above-described range.

<<Other Components>>

Optionally, the photosensitive composition according to the embodiment of the present invention may further include a sensitizer, a curing accelerator, a filler, a thermal curing accelerator, a plasticizer, and other auxiliary agents (for example, conductive particles, a filler, an antifoaming agent, a flame retardant, a leveling agent, a peeling accelerator, an aromatic chemical, a surface tension adjuster, or a chain transfer agent). By the composition appropriately including the components, properties such as film properties can be adjusted. The details of the components can be found in, for example, paragraph “0183” of JP2012-003225A (corresponding to paragraph “0237” of US2013/0034812A) and paragraphs “0101” to “0104” and “0107” to “0109” of JP2008-250074A, the contents of which are incorporated herein by reference. In addition, the photosensitive composition according to the embodiment of the present invention may optionally include a potential antioxidant. The potential antioxidant is a compound in which a portion that functions as the antioxidant is protected by a protective group and this protective group is desorbed by heating the compound at 100° C. to 250° C. or by heating the compound at 80° C. to 200° C. in the presence of an acid/a base catalyst. Examples of the potential antioxidant include a compound described in WO2014/021023A, WO2017/030005A, and JP2017-008219A. Examples of a commercially available product of the potential antioxidant include ADEKA ARKLS GPA-5001 (manufactured by Adeka Corporation).

For example, in a case where a film is formed by coating, the viscosity (23° C.) of the photosensitive composition according to the embodiment of the present invention is preferably 1 to 100 mPa·s. The lower limit is more preferably 2 mPa·s or higher and still more preferably 3 mPa·s or higher. The upper limit is preferably 50 mPa·s or lower, more preferably 30 mPa·s or lower, and still more preferably 15 mPa·s or lower.

<Storage Container>

A storage container of the photosensitive composition according to the embodiment of the present invention is not particularly limited, and a well-known storage container can be used. In addition, as the storage container, in order to suppress infiltration of impurities into the raw materials or the composition, a multilayer bottle in which a container inner wall having a six-layer structure is formed of six kinds of resins or a bottle in which a container inner wall having a seven-layer structure is formed of six kinds of resins is preferably used. Examples of the container include a container described in JP2015-123351A.

<Method of Preparing Photosensitive Composition>

The photosensitive composition according to the embodiment of the present invention can be prepared by mixing the above-described components with each other. During the preparation of the photosensitive composition, all the components may be dissolved or dispersed in a solvent at the same time to prepare the photosensitive composition. Optionally, two or more solutions or dispersion liquids to which the respective components are appropriately added may be prepared, and the solutions or dispersion liquids may be mixed with each other during use (during application) to prepare the photosensitive composition.

In addition, in a case where the photosensitive composition according to the embodiment of the present invention includes particles of a pigment or the like, it is preferable that a process of dispersing the particles is provided. Examples of a mechanical force used for dispersing the particles in the process of dispersing the particles include compression, squeezing, impact, shearing, and cavitation. Specific examples of the process include a beads mill, a sand mill, a roll mill, a ball mill, a paint shaker, a Microfluidizer, a high-speed impeller, a sand grinder, a flow jet mixer, high-pressure wet atomization, and ultrasonic dispersion. During the pulverization of the particles using a sand mill (beads mill), it is preferable that the process is performed under conditions for increasing the pulverization efficiency, for example, by using beads having a small size and increasing the filling rate of the beads. In addition, it is preferable that coarse particles are removed by filtering, centrifugal separation, and the like after pulverization. In addition, as the process and the disperser for dispersing the particles, a process and a disperser described in “Complete Works of Dispersion Technology, Johokiko Co., Ltd., Jul. 15, 2005”, “Dispersion Technique focusing on Suspension (Solid/Liquid Dispersion) and Practical Industrial Application, Comprehensive Reference List, Publishing Department of Management Development Center, Oct. 10, 1978”, and paragraph “0022” JP2015-157893A can be suitably used. In addition, in the process of dispersing the particles, particles may be refined in a salt milling step. A material, a device, process conditions, and the like used in the salt milling step can be found in, for example, JP2015-194521A and JP2012-046629A.

During the preparation of the photosensitive composition according to the embodiment of the present invention, it is preferable that the photosensitive composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable. The pore size of the filter is suitably about 0.01 to 7.0 μm and is preferably about 0.01 to 3.0 μm and more preferably about 0.05 to 0.5 μm. In a case where the pore size of the filter is in the above-described range, fine foreign matter can be reliably removed. In addition, it is preferable that a fibrous filter material is used. Examples of the fibrous filter material include polypropylene fiber, nylon fiber, and glass fiber. Specific examples include a filter cartridge of SBP type series (for example, SBP008), TPR type series (for example, TPROO2 or TPRO05), and SHPX type series (for example, SHPX003) all of which are manufactured by Roki Techno Co., Ltd. In a case where a filter is used, a combination of different filters (for example, a first filter and a second filter) may be used. At this time, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components.

<Method of Manufacturing Optical Filter>

Next, a method of manufacturing an optical filter using the photosensitive composition according to the embodiment of the present invention will be described. Examples of the kind of the optical filter include a color filter and an infrared transmitting filter.

The method of manufacturing an optical filter according to an embodiment of the present invention includes: a step (photosensitive composition layer forming step) of applying the above-described photosensitive composition according to the embodiment of the present invention to a support to form a photosensitive composition layer; a step (exposure step) of exposing (pulse exposure) the photosensitive composition layer to pulses of light in a pattern shape; and a step (development step) of forming a pixel by removing a non-exposed portion of the photosensitive composition layer by development. Hereinafter, the respective steps will be described.

(Photosensitive Composition Layer Forming Step)

In the photosensitive composition layer forming step, the above-described photosensitive composition according to the embodiment of the present invention is applied to a support to form a photosensitive composition layer. Examples of the support include a substrate formed of a material such as silicon, non-alkali glass, soda glass, PYREX (registered trade name) glass, or quartz glass. In addition, for example, an InGaAs substrate is preferably used. In addition, a charge coupled device (CCD), a complementary metal-oxide semiconductor (CMOS), a transparent conductive film, or the like may be formed on the support. In addition, a black matrix that separates pixels from each other may be formed on the support. In addition, optionally, an undercoat layer may be provided on the support to improve adhesiveness with a layer above the support, to prevent diffusion of materials, or to make a surface of the substrate flat.

As a method of applying the photosensitive composition to the support, a well-known method can be used. Examples of the well-known method include: a drop casting method; a slit coating method; a spray coating method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprint lithography method. The application method using an ink jet method is not particularly limited, and examples thereof include a method (in particular, pp. 115 to 133) described in “Extension of Use of Ink Jet—Infinite Possibilities in Patent—” (February, 2005, S.B. Research Co., Ltd.) and methods described in JP2003-262716A, JP2003-185831A, JP2003-261827A, JP2012-126830A, and JP2006-169325A. In addition, as the method of applying the photosensitive composition, methods described in WO2017/030174A and WO2017/018419A can also be used, the contents of which are incorporated herein by reference.

The photosensitive composition may be dried (pre-baked) after being applied to the support. In a case where pre-baking is performed, the pre-baking temperature is preferably 150° C. or lower, more preferably 120° C. or lower, and still more preferably 110° C. or lower. The lower limit is, for example, 50° C. or higher or 80° C. or higher. The pre-baking time is preferably 10 to 3000 seconds, more preferably 40 to 2500 seconds, and still more preferably 80 to 2200 seconds. Drying can be performed using a hot plate, an oven, or the like.

(Exposure Step)

Next, the photosensitive composition layer formed on the support as described above is exposed (pulse exposure) to pulses of light in a pattern shape. By exposing the photosensitive composition layer to pulses of light through a mask having a predetermined mask pattern, the photosensitive composition layer can be exposed to pulses of light in a pattern shape. As a result, the exposed portion of the photosensitive composition layer can be cured.

The light used for the pulse exposure may be light having a wavelength of longer than 300 nm or light having a wavelength of 300 nm or shorter. From the viewpoint of easily obtaining excellent curing properties, the light used for the exposure is preferably light having a wavelength of 300 nm or shorter, more preferably light having a wavelength of 270 nm or shorter, and still more preferably light having a wavelength of 250 nm or shorter. In addition, the above-described light is preferably light having a wavelength of 180 nm or longer. Specific examples of the light include a KrF ray (wavelength: 248 nm) and an ArF ray (wavelength: 193 nm). From the viewpoint of easily obtaining higher curing properties, a KrF ray (wavelength: 248 nm) is preferable.

It is preferable that the pulse exposure condition is the following condition. From the viewpoint of instantaneously generating a large amount of an active species such as a radical easily, the pulse duration is preferably 100 nanoseconds (ns) or shorter, more preferably 50 nanoseconds or shorter, and still more preferably 30 nanoseconds or shorter. The lower limit of the pulse duration is not particularly limited and may be 1 femtoseconds (fs) or longer or 10 femtoseconds (fs) or longer. From the viewpoint of curing properties, the frequency is preferably 1 kHz or higher, more preferably 2 kHz or higher, and still more preferably 4 kHz or higher. From the viewpoint of easily suppressing deformation of a substrate or the like caused by exposure heat, the upper limit of the frequency is preferably 50 kHz or lower, more preferably 20 kHz or lower, and still more preferably 10 kHz or lower. From the viewpoint of curing properties, the maximum instantaneous illuminance is preferably 50000000 W/m² or higher, more preferably 100000000 W/m² or higher, and still more preferably 200000000 W/m² or higher. In addition, from the viewpoint of high illuminance reciprocity failure, the upper limit of the maximum instantaneous illuminance is preferably 1000000000 W/m² or lower, more preferably 800000000 W/m² or lower, and still more preferably 500000000 W/m² or lower. The exposure dose is preferably 1 to 1000 mJ/cm². The upper limit is preferably 500 mJ/cm² or lower and more preferably 200 mJ/cm² or lower. The lower limit is preferably 10 mJ/cm² or higher, more preferably 20 mJ/cm² or higher, and still more preferably 30 mJ/cm² or higher.

The oxygen concentration during exposure can be appropriately selected. The exposure may be performed not only in air but also in a low-oxygen atmosphere having an oxygen concentration of 19 vol % or lower (for example, 15 vol %, 5 vol %, or substantially 0 vol %) or in a high-oxygen atmosphere having an oxygen concentration of higher than 21 vol % (for example, 22 vol %, 30 vol %, or 50 vol %).

(Development Step)

Next, after the exposure step, a pixel (pattern) is formed by removing a non-exposed portion of the photosensitive composition layer by development. The non-exposed portion of the photosensitive composition layer can be removed by development using a developer. As a result, the non-exposed portion of the photosensitive composition layer in the exposure step is eluted into the developer, and only the portion that is photocured in the above-described exposure step remains on the support. For example, the temperature of the developer is preferably 20° C. to 30° C. The development time is preferably 20 to 180 seconds. In addition, in order to further improve residue removing properties, a step of shaking the developer off per 60 seconds and supplying a new developer may be repeated multiple times.

As the developer, an alkaline aqueous solution in which the above alkaline agent is diluted with pure water is preferable. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropyl ammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, or 1,8-diazabicyclo[5.4.0]-7-undecene; and an inorganic alkaline compound such as sodium hydroxide, potassium hydroxide, sodium carbonate, sodium bicarbonate, sodium silicate, or sodium metasilicate. From the viewpoints of environment and safety, it is preferable that the alkaline agent is a compound having a high molecular weight. A concentration of the alkaline agent in the alkaline aqueous solution is preferably 0.001 to 10 mass % and more preferably 0.01 to 1 mass %. In addition, the developer may further include a surfactant. Examples of the surfactant include the above-described surfactants. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In a case where the alkaline aqueous solution is used as the developer, it is preferable that the layer is rinsed with pure water after development.

After the development and drying, an additional exposure treatment or a heating treatment (post-baking) can also be performed. The additional exposure treatment or the post-baking is a treatment which is performed after development to completely cure the film. In a case where the additional exposure treatment is performed, the light used for exposure is preferably light having a wavelength of 400 nm or shorter.

It is preferable that the thickness of the pixel (pattern) to be formed is appropriately selected depending on the kind of the pixel. For example, the thickness of the pixel is preferably 2.0 μm or less, more preferably 1.0 μm or less, and still more preferably 0.3 to 1.0 μm. The upper limit is preferably 0.8 μm or less and more preferably 0.6 μm or less. The lower limit value is preferably 0.4 μm or more.

In addition, it is preferable that the size (line width) of the pixel (pattern) to be formed is selected depending on the use or the kind of the pixel. For example, the size of the pixel is preferably 2.0 μm or less. The upper limit is preferably 1.0 μm or less and more preferably 0.9 μm or less. The lower limit value is preferably 0.4 μm or more.

In a case where an optical filter including plural kinds of pixels is manufactured, at least one kind of pixel may be formed through the above-described steps, and it is preferable that a pixel to be initially formed (the first kind of pixel) is formed through the above-described steps. A pixel to be secondly or subsequently formed (the second or subsequent kind of pixel) may be formed through the above-described steps or may be formed by exposure using continuous light.

### EXAMPLES

Hereinafter, the present invention will be described in detail using examples. Materials, used amounts, ratios, treatment details, treatment procedures, and the like shown in the following examples can be appropriately changed within a range not departing from the scope of the present invention. Accordingly, the scope of the present invention is not limited to the following specific examples.

<Measurement of Weight-Average Molecular Weight (Mw) of Resin>

The weight-average molecular weight of the resin can be measured under the following conditions by gel permeation chromatography (GPC).

Kind of column: a column in which TOSOH TSK gel Super HZM-H, TOSOH TSK gel Super HZ4000, and TOSOH TSK gel Super HZ2000 were linked to each other

Developing solvent: tetrahydrofuran

Column temperature: 40° C.

Flow rate (sample injection volume): 1.0 μL (sample concentration: 0.1 mass %)

Device name: HLC-8220 GPC (manufactured by Tosoh Corporation)

Detector: refractive index (RI) detector

Calibration curve base resin: a polystyrene resin

<Preparation of Photosensitive Composition>

The following raw materials were mixed, and the obtained mixture was filtered through a nylon filter (manufactured by Pall Corporation) having a pore size of 0.45 μm. This way, photosensitive compositions (compositions 1 to 26, R1 to R3) having a concentration of solid contents of 20 mass % were prepared. The concentration of solid contents of each of the compositions 1 to 8, 10 to 26, and R1 to R3 was adjusted by changing the mixing amount of propylene glycol monomethyl ether acetate (PGMEA). In addition, the solid content concentration of the composition 9 was adjusted by changing the mixing amount of a mixed solvent (PGMEA:polyethylene glycol monomethyl ether=9:1 (mass ratio)) including PGMEA and polyethylene glycol monomethyl ether. Numerical values of the mixing amounts in the following table are represented by “part(s) by mass”.

TABLE 1

| | Pigment | | | | Radically | | Photoradical | | | | Chain Transfer | | | |
|---|---|---|---|---|---|---|---|---|---|---|---|---|---|---|
| | Dispersion | | | | Polymezable | | Polymerization | | | | Agent, Radical | | | |
| | Liquid | | Resin | | Monomer | | Initiator | | Surfactant | | Trapping Agent | | Additive | |
| | | Mixing | | Mixing | | Mixing | | Mixing | | Mixing | | Mixing | | Mixing |
| | Kind | Amount | Kind | Amount | Kind | Amount | Kind | Amount | Kind | Amount | Kind | Amount | Kind | Amount |
| Composition 1 | A1 | 800 | B1 | 7 | M1 | 11 | I1 | 3 | W1 | 0.1 | CT1 | 1.9 | — | — |
| | | | | | | | I2 | 2 | | | | | | |
| Composition 2 | A1 | 800 | B1 | 7 | M1 | 11 | I1 | 2 | W1 | 0.1 | CT1 | 3.8 | | — |
| | | | | | | | I2 | 2 | | | | | | |
| Composition 3 | A1 | 800 | B1 | 7 | M1 | 11 | I1 | 3 | W1 | 0.1 | CT1 | 5.7 | — | — |
| | | | | | | | I2 | 2 | | | | | | |
| Composition 4 | A1 | 800 | B1 | 7 | M1 | 11 | I1 | 3 | W1 | 0.1 | RT1 | 1.9 | — | — |
| | | | | | | | I2 | 2 | | | | | | |
| Composition 5 | A1 | 800 | B1 | 7 | M1 | 11 | I1 | 3 | W1 | 0.1 | RT1 | 3.8 | — | — |
| | | | | | | | I2 | 2 | | | | | | |
| Composition 6 | A1 | 800 | B1 | 7 | M1 | 8 | I1 | 3 | W1 | 0.1 | RT1 | 5.7 | — | — |
| | | | | | | 3 | I2 | 2 | | | | | | |
| Composition 7 | A1 | 800 | B1 | 7 | M1 | 11 | — | — | W1 | 0.1 | CT2 | 3.8 | — | — |
| Composition 8 | A1 | 800 | B1 | 7 | M1 | 11 | I1 | 3 | W1 | 0.1 | RT2 | 3.8 | — | — |
| | | | | | | | I2 | 2 | | | | | | |
| Composition 9 | A1 | 800 | B1 | 7 | M1 | 11 | I1 | 3 | W1 | 0.1 | CT1 | 3.8 | — | — |
| | | | | | | | I2 | 2 | | | | | | |
| Composition 10 | A1 | 800 | B1 | 7 | M1 | 11 | I1 | 3 | W1 | 0.1 | RT1 | 3.8 | UV1 | 1.9 |
| | | | | | | | I2 | 2 | | | | | | |
| Composition 11 | A2 | 800 | B1 | 6 | M1 | 12 | I1 | 6 | W1 | 0.1 | CT1 | 1.9 | — | — |
| Composition 12 | A2 | 800 | B1 | 6 | M1 | 12 | I1 | 6 | W1 | 0.1 | CT1 | 5.7 | — | — |
| Composition 13 | A3 | 800 | B1 | 4 | M1 | 4 | I1 | 3 | W1 | 0.1 | CT1 | 1.9 | — | — |
| Composition 14 | A3 | 800 | B1 | 4 | M1 | 4 | I1 | 3 | W1 | 0.1 | CT1 | 5.7 | — | — |
| Composition 15 | A1 | 800 | B1 | 7 | M1 | 11 | I3 | 3 | W1 | 0.1 | CT1 | 1.9 | — | — |
| | | | | | | | I2 | 2 | | | | | | |
| Composition 16 | A1 | 800 | B1 | 7 | M1 | 11 | I3 | 3 | W1 | 0.1 | CT1 | 5.7 | — | — |
| | | | | | | | I2 | 2 | | | | | | |
| Composition 17 | A1 | 800 | B1 | 4 | M1 | 5 | I1 | 3 | W2 | 0.1 | CT1 | 1.9 | — | — |
| | | | B2 | 3 | M2 | 6 | 12 | 2 | | | | | | |
| Composition 18 | A1 | 800 | B1 | 4 | M1 | 5 | I1 | 3 | W2 | 0.1 | CT1 | 5.7 | — | — |
| | | | B2 | 3 | M2 | 6 | I2 | 2 | | | | | | |
| Composition 19 | A1 | 800 | B1 | 7 | M1 | 11 | I1 | 3 | W1 | 0.1 | CT3 | 3.8 | — | — |
| | | | | | | | I2 | 2 | | | | | | |
| Composition 20 | A1 | 800 | B1 | 7 | M1 | 11 | I1 | 3 | W1 | 0.1 | CT4 | 3.8 | — | — |
| | | | | | | | I2 | 2 | | | | | | |
| Composition 21 | A1 | 800 | B1 | 7 | M1 | 11 | I1 | 3 | W1 | 0.1 | CT5 | 3.8 | — | — |
| | | | | | | | I2 | 2 | | | | | | |
| Composition 22 | A1 | 800 | B1 | 7 | M1 | 11 | I1 | 3 | W1 | 0.1 | CT6 | 3.8 | — | — |
| | | | | | | | I2 | 2 | | | | | | |
| Composition 23 | A1 | 800 | B1 | 7 | M1 | 11 | I1 | 3 | W1 | 0.1 | RT3 | 3.8 | — | — |
| | | | | | | | I2 | 2 | | | | | | |
| Composition 24 | A1 | 800 | B1 | 7 | M1 | 11 | I1 | 3 | W1 | 0.1 | RT4 | 3.8 | — | — |
| | | | | | | | I2 | 2 | | | | | | |
| Composition 25 | A1 | 800 | B1 | 7 | M1 | 11 | I1 | 3 | W1 | 0.1 | RT5 | 3.8 | — | — |
| | | | | | | | I2 | 2 | | | | | | |
| Composition 26 | A1 | 800 | B1 | 7 | M1 | 11 | I1 | 3 | W1 | 0.1 | RT6 | 3.8 | — | — |
| | | | | | | | I2 | 2 | | | | | | |
| Composition R1 | A1 | 800 | B1 | 7 | M1 | 11 | I1 | 3 | W1 | 0.1 | — | — | — | — |
| | | | | | | | I2 | 2 | | | | | | |
| Composition R2 | A1 | 800 | B1 | 7 | M1 | 11 | I1 | 2 | W1 | 0.1 | — | — | — | — |
| | | | | | | | I2 | 1 | | | | | | |
| Composition R3 | A1 | 800 | B1 | 7 | M1 | 11 | I1 | 4 | W1 | 0.1 | — | — | — | — |
| | | | | | | | I2 | 3 | | | | | | |

The raw materials shown above in the table are as follows.

(Pigment Dispersion Liquid)

A1: a pigment dispersion liquid prepared using the following method

10.7 parts by mass of C.I. Pigment Green 58, 2.7 parts by mass of C.I. Pigment Yellow 185, 1.3 parts by mass of a pigment derivative 1, 5.3 parts by mass of a dispersant 1, and 80 parts by mass of propylene glycol monomethyl ether acetate (PGMEA) were prepared to prepare a mixed solution, 230 parts by mass of zirconia beads having a diameter of 0.3 mm was further added to the mixed solution, the mixed solution was dispersed using a paint shaker for 3 hours, and the beads were separated by filtration. As a result, a pigment dispersion liquid A1 was prepared. In this the pigment dispersion liquid A1, the concentration of solid contents was 20 mass %, and the pigment content was 13.4 mass %.

Pigment derivative 1: a compound having the following structure

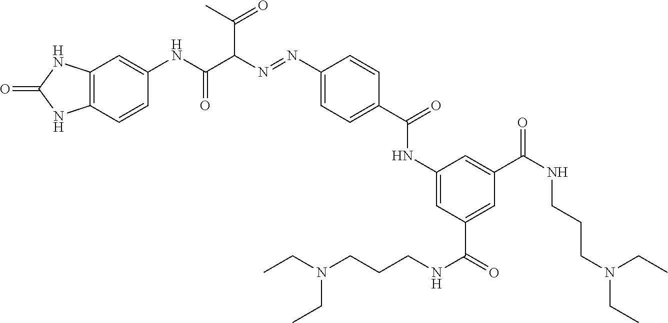 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

Dispersant 1: a resin having the following structure (Mw=26000, a numerical value added to a main chain represents a molar ratio, and a numerical value added to a side chain represents the number of repeating units)

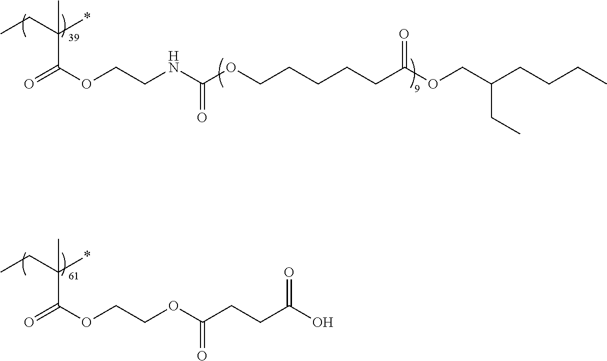

A2: a pigment dispersion liquid prepared using the following method

11.8 parts by mass of C.I. Pigment Blue 15:6, 3.0 parts by mass of C.I. Pigment Violet 23, 5.2 parts by mass of a dispersant 2, and 80 parts by mass of propylene glycol monomethyl ether acetate (PGMEA) were mixed with each other to obtain a mixed solution, 230 parts by mass of zirconia beads having a diameter of 0.3 mm was added to the mixed solution, the mixed solution was dispersed using a paint shaker for 3 hours, and the beads were separated by filtration. As a result, a pigment dispersion liquid A2 was prepared. In this the pigment dispersion liquid, the concentration of solid contents was 20 mass %, and the pigment content was 14.8 mass %.

Dispersant 2: a resin having the following structure (a numerical value added to a main chain represents a molar ratio, and a numerical value added to a side chain represents the number of repeating units, Mw: 20000, C═C value: 0.7 mmol/g, acid value: 72 mgKOH/g)

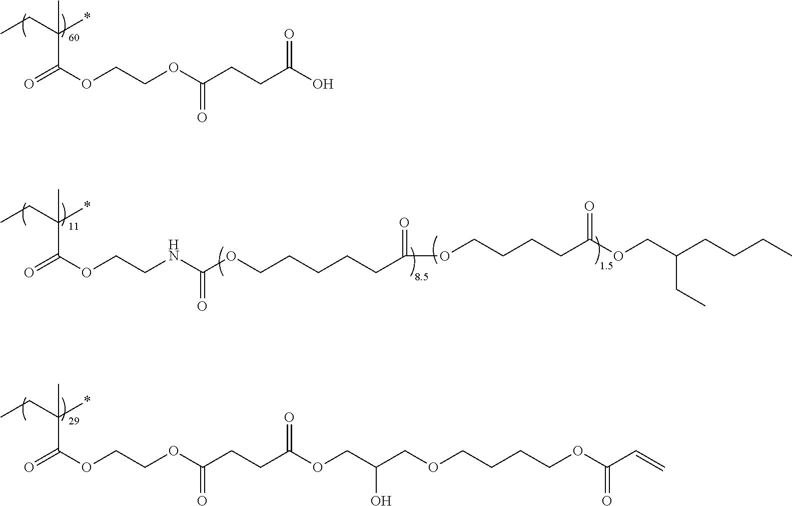

A3: a pigment dispersion liquid prepared using the following method

11.8 parts by mass of C.I. Pigment Red 254, 3.0 parts by mass of C.I. Pigment Yellow 139, 5.2 parts by mass of a dispersant 2, and 80 parts by mass of propylene glycol monomethyl ether acetate (PGMEA) were mixed with each other to obtain a mixed solution, 230 parts by mass of zirconia beads having a diameter of 0.3 mm was added to the mixed solution, the mixed solution was dispersed using a paint shaker for 3 hours, and the beads were separated by filtration. As a result, a pigment dispersion liquid A3 was prepared. In this the pigment dispersion liquid, the concentration of solid contents was 20 mass %, and the pigment content was 14.8 mass %.

(Resin)

B1: a resin having the following structure (a numerical value added to a main chain represents a molar ratio; Mw: 10,000, acid value: 70 mgKOH/g)

B2: ACRYBASE FF-426 (manufactured by Fujikura Kasei Co., Ltd., alkali-soluble resin)

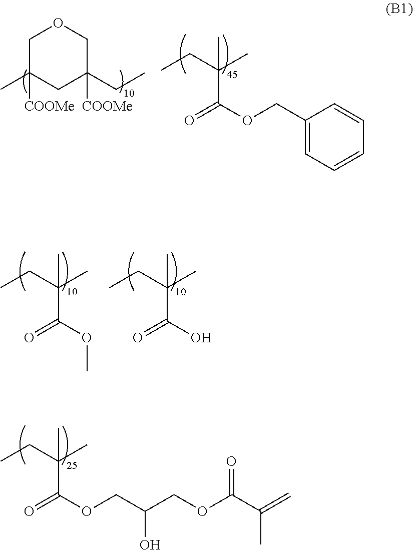

(Radically Polymerizable Monomer)

M1: a compound having the following structure (acrylate monomer, radically polymerizable group value: 11.4 mmol/g)

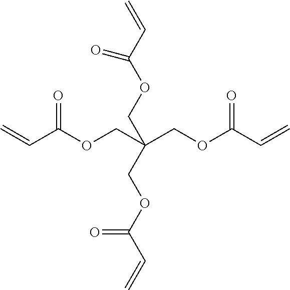 [SMILES: C=CC(=O)OCC(COC(=O)C=C)(COC(=O)C=C)COC(=O)C=C]

M2: OGSOL EA-0300 (manufactured by Osaka Gas Chemicals Co., Ltd., a (meth)acrylate monomer having a fluorene skeleton)

(Photoradical Polymerization Initiator)

I1: IRGACURE-OXE01 (manufactured by BASF SE, an oxime compound)

I2: a compound (oxime compound) having the following structure

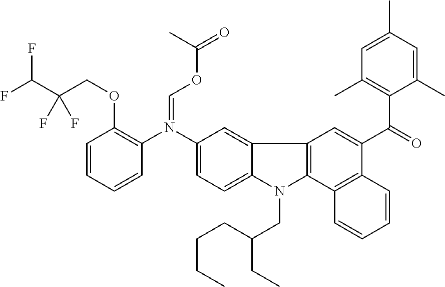

I3: IRGACURE-379 (manufactured by BASF SE, an α-aminoalkylphenone compound)

(Surfactant)

W1: KF-6002 (manufactured by Shin-Etsu Chemical Co., Ltd.)

W2: a compound having the following structure (Mw:14000, a numerical value of “%” representing the proportion of a repeating unit is mol %)

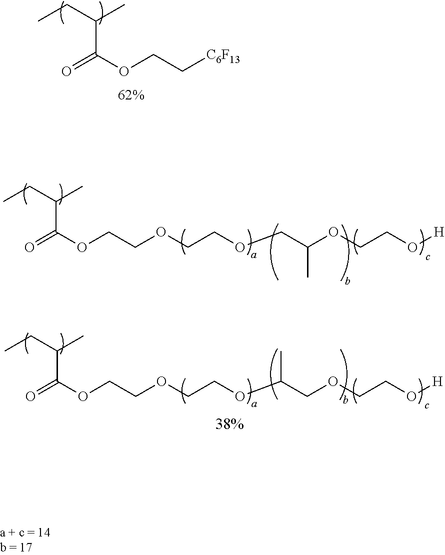

(Chain Transfer Agent)

CT1: pentaerythritol tetra(3-mercaptopropionate)

CT2: 2,4-diphenyl-4-methyl-1-pentene

CT3: cyanomethyl dodecyl trithiocarbonate

CT4: SANCELER M (a thiol compound, manufactured by Sanshin Chemical Industry Co., Ltd.)

CT5: 2-cyano-2-propyl dodecyl trithiocarbonate

CT6: KARENZ MT BD1 (a thiol compound, manufactured by Showa Denko K.K.).

(Radical Trapping Agent)

RT1: 2,2,6,6-tetramethylpiperidine 1-oxyl

RT2: 2,2-diphenyl-1-picrylhydrazyl

RT3: ADEKA STAB AO-20 (manufactured by Adeka Corporation)

RT4: ADEKA STAB LA-52 (manufactured by Adeka Corporation)

RT5: triphenylverdazyl

RT6: ADEKA STAB AO-60G (manufactured by Adeka Corporation)

(Additives)

UV1: UV-503 (manufactured by Daito Chemical Co., Ltd., an ultraviolet absorber)

<Evaluation>

Each of the photosensitive compositions obtained as described above was applied to an 8-inch (203.2 mm) silicon wafer with an undercoat layer with a spin coating method such that the thickness of the applied film was 0.5 μm. Next, the coating film was post-baked using a hot plate at 100° C. for 2 minutes. Next, using a KrF scanner exposure device, pulse exposure was performed under the following condition through a mask having a Bayer pattern with a size of 0.9 cm×0.9 cm. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the coating film was heated (post-baked) using a hot plate at 200° C. for 5 minutes. As a result, a pixel (pattern) was formed. The pulse exposure condition was as follows.

Exposure light: KrF ray (wavelength: 248 nm) Exposure dose: 200 mJ/cm² in Test Examples 1 to 26; 200 mJ/cm², 250 mJ/cm², or 300 mJ/cm² in Test Examples R1 to R3

Maximum instantaneous illuminance: 250000000 W/m² (average illuminance: 30000 W/m²)

Pulse duration: 30 nanoseconds

Frequency: 4 kHz

The formed image (pattern) was observed with a scanning electron microscope to measure the line width of the pixel. The following table shows the line width of the pixel (pattern) at each of the exposure doses.

TABLE 2

| | Photosensitive | Exposure Dose | | |
|---|---|---|---|---|
| | Composition | 200 | 250 | 300 |
| | Used | mJ/cm² | mJ/cm² | mJ/cm² |
| Test Example 1 | Composition 1 | 1.00 μm | — | — |
| Test Example 2 | Composition 2 | 1.04 μm | — | — |
| Test Example 3 | Composition 3 | 1.06 μm | — | — |
| Test Example 4 | Composition 4 | 0.94 μm | — | — |
| Test Example 5 | Composition 5 | 0.91 μm | — | — |
| Test Example 6 | Composition 6 | 0.88 μm | — | — |
| Test Example 7 | Composition 7 | 1.01 μm | — | — |
| Test Example 8 | Composition 8 | 0.93 μm | — | — |
| Test Example 9 | Composition 9 | 1.04 μm | — | — |
| Test Example 10 | Composition 10 | 0.87 μm | — | — |
| Test Example 11 | Composition 11 | 1.01 μm | — | — |
| Test Example 12 | Composition 12 | 1.07 μm | — | — |
| Test Example 13 | Composition 13 | 0.99 μm | — | — |
| Test Example 14 | Composition 14 | 1.05 μm | — | — |
| Test Example 15 | Composition 15 | 1.02 μm | — | — |
| Test Example 16 | Composition 16 | 1.08 μm | — | — |
| Test Example 17 | Composition 17 | 1.01 μm | — | — |
| Test Example 18 | Composition 18 | 1.07 μm | — | — |
| Test Example 19 | Composition 19 | 1.03 μm | — | — |
| Test Example 20 | Composition 20 | 1.01 μm | — | — |
| Test Example 21 | Composition 21 | 1.02 μm | — | — |
| Test Example 22 | Composition 22 | 1.02 μm | — | — |
| Test Example 23 | Composition 23 | 0.92 μm | — | — |
| Test Example 24 | Composition 24 | 0.94 μm | — | — |
| Test Example 25 | Composition 25 | 0.93 μm | — | — |
| Test Example 26 | Composition 26 | 0.92 μm | — | — |
| Test Example R1 | Composition R1 | 0.96 μm | 0.97 μm | 0.97 μm |
| Test Example R2 | Composition R2 | 0.96 μm | 0.96 μm | 0.97 μm |
| Test Example R3 | Composition R3 | 0.97 μm | 0.97 μm | 0.98 μm |

As shown in the table above, in Test Examples 1 to 3, 7, 9, and 11 to 22 in which the compositions 1 to 3, 7, 9, and 11 to 22 including the chain transfer agent were used, the line width of the pixel (pattern) was able to be adjusted to be more than that in Test Examples R1 to R3. In addition, in Test Examples 4 to 6, 8, 10, and 23 to 26 in which the compositions 4 to 6, 8, 10, and 23 to 26 including the radical trapping agent were used, the line width of the pixel (pattern) was able to be adjusted to be less than that in Test Examples R1 to R3. This way, in the present invention, the line width of the obtained pattern was able to be adjusted without changing an opening size of a mask.

In addition, the pixels obtained in Test Examples 1 to 26 were sufficiently cured up to the bottom portion and had excellent properties such as adhesiveness or solvent resistance as in the pixels obtained in Test Examples R1 to R3.

On the other hand, in Test Examples R1 to R3, even in a case where the exposure dose changed, the line width of the obtained pattern did not substantially change.

Even in a case where compositions were prepared using the same method as that of the compositions 1 to 26 except that a pigment dispersion liquid A100 prepared using the following method was used instead of the pigment dispersion liquid A1, the same effects as those of the Test Examples 1 to 26 were able to be obtained.

(Pigment Dispersion Liquid A100)

10.7 parts by mass of C.I. Pigment Green 36, 2.7 parts by mass of C.I. Pigment Yellow 185, 1.3 parts by mass of the pigment derivative 1, 5.3 parts by mass of the dispersant 1, and 80 parts by mass of PGMEA were mixed with each other to obtain a mixed solution, 230 parts by mass of zirconia beads having a diameter of 0.3 mm was added to the mixed solution, the mixed solution was dispersed using a paint shaker for 3 hours, and the beads were separated by filtration. As a result, a pigment dispersion liquid A100 was prepared.

What is claimed is:

1. A photosensitive composition for pulse exposure comprising:
a radically polymerizable compound;
a photoradical polymerization initiator; and
at least one selected from a chain transfer agent or a radical trapping agent.

2. The photosensitive composition according to claim 1, further comprising:
a coloring material.

3. The photosensitive composition according to claim 1,
wherein the chain transfer agent is at least one selected from a thiol compound, a thiocarbonylthio compound, or an aromatic α-methyl alkenyl dimer.

4. The photosensitive composition according to claim 1,
wherein the radical trapping agent is at least one selected from a hindered phenol compound, a hindered amine compound, an N-oxyl compound, a hydrazyl compound, or a verdazyl compound.

5. The photosensitive composition according to claim 1,
wherein a content of the chain transfer agent is 0.01% to 10 mass % with respect to a total solid content of the photosensitive composition.

6. The photosensitive composition according to claim 1,
wherein a content of the chain transfer agent is 0.1 to 100 parts by mass with respect to 100 parts by mass of the radically polymerizable compound.

7. The photosensitive composition according to claim 1,
wherein a content of the chain transfer agent is 0.2 to 200 parts by mass with respect to 100 parts by mass of the photoradical polymerization initiator.

8. The photosensitive composition according to claim 1,
wherein a content of the radical trapping agent is 0.01% to 10 mass % with respect to a total solid content of the photosensitive composition.

9. The photosensitive composition according to claim 1,
wherein a content of the radical trapping agent is 0.1 to 100 parts by mass with respect to 100 parts by mass of the radically polymerizable compound.

10. The photosensitive composition according to claim 1,
wherein a content of the radical trapping agent is 0.2 to 200 parts by mass with respect to 100 parts by mass of the photoradical polymerization initiator.

11. The photosensitive composition according to claim 1, further comprising:
a resin having an acid group.

12. The photosensitive composition according to claim 1, which is a photosensitive composition for pulse exposure to light having a wavelength of 300 nm or shorter.

13. The photosensitive composition according to claim 1, which is a photosensitive composition for pulse exposure under a condition of a maximum instantaneous illuminance of 50000000 W/m² or higher.

14. The photosensitive composition according to claim 1, which is a photosensitive composition for a solid-state imaging element.

15. The photosensitive composition according to claim 1, which is a photosensitive composition for a color filter.
